(19) United States
(12) Patent Application Publication
(10) Pub. No.: US 2023/0060443 A1
(43) Pub. Date: Mar. 2, 2023

(54) DISPLAY DEVICE

(71) Applicant: Samsung Display Co., LTD., Yongin-si (KR)

(72) Inventors: Hyung Il JEON, Yongin-si (KR); Sung Kook PARK, Yongin-si (KR); Sung Eun BAEK, Yongin-si (KR); Ki Seong SEO, Yongin-si (KR); So Yeon YOON, Yongin-si (KR); Jin Woo CHOI, Yongin-si (KR)

(73) Assignee: Samsung Display Co., LTD., Yongin-si (KR)

(21) Appl. No.: 17/869,088

(22) Filed: Jul. 20, 2022

(30) Foreign Application Priority Data
Aug. 24, 2021 (KR) 10-2021-0111918

(51) Int. Cl. H01L 25/16; H01L 33/54

(52) U.S. Cl. CPC H01L 25/167; H01L 33/54; H01L 24/05

(57) ABSTRACT

A display device includes a first electrode disposed on a substrate. A light blocking layer is disposed on the substrate, the light blocking layer includes a recessed portion recessed toward the first electrode. Holes exposing the first electrode are formed in the recessed portion of the light blocking layer. Light emitting elements are disposed in the holes, each of the light emitting elements including a first end electrically contacting the first electrode. A second electrode is disposed on the light blocking layer, the second electrode electrically contacts a second end of each of the light emitting elements. A light conversion pattern is disposed in the recessed portion of the light blocking layer.

### CROSS-REFERENCE TO RELATED APPLICATION(S)

This application claims priority to and benefits of Korean Patent Application No. 10-2021-0111918 under 35 U.S.C. § 119, filed on Aug. 24, 2021 in the Korean Intellectual Property Office, the entire contents of which are incorporated herein by reference.

### BACKGROUND

### 1. Technical Field

The disclosure relates to a display device.

### 2. Description of the Related Art

In recent years, as interest in information display is increasing, research and development for a display device are continuously being conducted.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

An object of the disclosure is to provide a display device capable of minimizing reflection of external light.

An object of the disclosure is to provide a display device capable of improving light output efficiency.

A display device may include a first electrode disposed on a substrate; a light blocking layer disposed on the substrate, the light blocking layer including a recessed portion recessed toward the first electrode; and holes in the recessed portion exposing the first electrode; light emitting elements disposed in the holes, each of the light emitting elements including a first end electrically contacting the first electrode; a second electrode disposed on the light blocking layer, the second electrode electrically contacting a second end of each of the light emitting elements; and a light conversion pattern disposed in the recessed portion of the light blocking layer.

According to an embodiment, an outer circumferential surface between the first end and the second end of each of the light emitting elements may contact the light blocking layer.

According to an embodiment, the light blocking layer may include a black matrix material.

According to an embodiment, the light conversion pattern may include a color conversion layer that converts light of a first color emitted from the light emitting elements into light of a second color.

According to an embodiment, the light conversion pattern may include a color filter disposed on the color conversion layer, the color filter transmitting the light of the second color.

According to an embodiment, the display device may further include a first reflective member surrounding an outer circumferential surface between the first end and the second end of each of the light emitting elements.

According to an embodiment, the display device may further include a second reflective member overlapping a side surface of the recessed portion of the light blocking layer in a plan view and not substantially overlapping a bottom surface of the recessed portion of the light blocking layer in a plan view.

According to an embodiment, the second reflective member may be disposed between the second electrode and the light conversion pattern.

According to an embodiment, the second reflective member may be disposed between the light blocking layer and the second electrode.

According to an embodiment, the light blocking layer may include a metal oxide.

According to an embodiment, the light blocking layer may include a metal layer disposed on the substrate; and a metal oxide layer disposed on a surface of the metal layer.

According to an embodiment, the display device may further include an insulating layer disposed between the first electrode and the light blocking layer and disposed between the light blocking layer and the light emitting elements.

According to an embodiment, the first electrode may include a conductive material that reflects light, and the second electrode may include a transparent conductive material that transmits light.

According to an embodiment, each of the light emitting elements may include a second semiconductor layer electrically connected to the first electrode; a first semiconductor layer electrically connected to the second electrode; and an active layer disposed between the second semiconductor layer and the first semiconductor layer.

According to an embodiment, the display device may further include a pixel defining layer disposed between an edge of the first electrode and the light blocking layer, the pixel defining layer defining an emission area.

A display device may include a first electrode disposed on a substrate; light emitting elements disposed on the first electrode, each of the light emitting elements including a first end electrically contacting the first electrode; a second electrode disposed on the light emitting elements, the second electrode electrically contacting a second end of each of the light emitting elements; and a light blocking layer disposed between the first electrode and the second electrode and disposed between the light emitting elements. The light blocking layer may include a metal oxide.

According to an embodiment, the light blocking layer may include a metal layer disposed on the substrate; and a metal oxide layer disposed on a surface of the metal layer.

According to an embodiment, the display device may further include an insulating layer disposed between the first electrode and the light blocking layer and disposed between the light blocking layer and the light emitting elements.

According to an embodiment, the display device may further include a first reflective member surrounding an outer circumferential surface between the first end and the second end of each of the light emitting elements.

According to an embodiment, the display device may further include a bank disposed on the second electrode, the bank including an opening corresponding to the light emitting elements; and a light conversion pattern disposed in the opening of the bank, and the bank may include a metal oxide.

According to an embodiment, the display device may further include a second reflective member overlapping a side surface of the opening of the bank in a plan view.

A display device may include a first electrode disposed on a substrate; light emitting elements disposed on the first electrode, each of the light emitting elements including a first end electrically contacting the first electrode; a second electrode disposed on the light emitting elements, the second electrode electrically contacting a second end of each of the light emitting elements; a light blocking layer disposed between the first electrode and the second electrode and disposed between the light emitting elements; a bank disposed on the second electrode, the bank including an opening corresponding to the light emitting elements; a light conversion pattern disposed in the opening of the bank; and a reflective member overlapping a side surface of the opening of the bank in a plan view.

The display device according to embodiments may include the bank disposed to surround the light emitting element and overlapping most of the first electrode. The bank may include a light blocking material such as a black matrix or a black metal oxide layer. Therefore, reflection of external light by the first electrode may be minimized.

The display device may further include the first reflective member that surrounds an outer circumferential surface of the light emitting element and/or the second reflective member that covers or overlaps a side surface (or an inclined surface) of the bank. Therefore, the light emitted from the light emitting element may further proceed in an image display direction by the first reflective member and/or the second reflective member, and light output efficiency of the light emitting element may be improved.

Effects according to an embodiment is not limited by the effects described above, and more various effects are included in the specification.

### BRIEF DESCRIPTION OF THE DRAWINGS

The above and other features of the disclosure will become more apparent by describing in further detail embodiments thereof with reference to the accompanying drawings, in which:

FIG. 1 is a schematic plan view schematically illustrating a display device according to embodiments of the disclosure;

FIGS. 2A and 2B are schematic circuit diagrams illustrating an electrical connection relationship between components included in a pixel included in the display device of FIG. 1 according to an embodiment;

FIG. 3 schematically illustrates the pixel included in the display device of FIG. 1, and is a schematic plan view of the pixel viewed from an upper portion based on a light emitting unit shown in FIGS. 2A and 2B;

FIGS. 4A, 4B, and 4C are schematic cross-sectional views illustrating an embodiment of a pixel taken along line I-I′ of FIG. 3;

FIGS. 5A and 5B are schematic cross-sectional views illustrating an embodiment of the pixel taken along line I-I′ of FIG. 3;

FIGS. 6A, 6B, and 6C are schematic cross-sectional views illustrating an embodiment of the pixel taken along line I-I′ of FIG. 3;

FIGS. 7A and 7B are schematic cross-sectional views illustrating an embodiment of the pixel taken along line I-I′ of FIG. 3;

FIGS. 8A, 8B, and 8C are schematic cross-sectional views illustrating an embodiment of the pixel taken along line I-I′ of FIG. 3;

FIGS. 9A, 9B, and 9C are schematic cross-sectional views illustrating an embodiment of the pixel taken along line I-I′ of FIG. 3;

FIG. 10 is a schematic diagram illustrating a light emitting element according to an embodiment; and

FIGS. 11 to 14 are schematic diagrams illustrating application examples of a display device according to embodiments.

### DETAILED DESCRIPTION OF THE EMBODIMENTS

The disclosure may be modified in various manners and have various forms. Therefore, embodiments will be illustrated in the drawings and will be described in detail in the specification. However, it should be understood that the disclosure is not intended to be limited to the disclosed described forms, and the disclosure includes all modifications, equivalents, and substitutions within the spirit and technical scope of the disclosure.

Similar reference numerals are used for similar components in describing each drawing. In the accompanying drawings, the dimensions of the structures are shown enlarged from the actual dimensions for the sake of clarity of the disclosure. For example, in the drawings, sizes, thicknesses, ratios, and dimensions of the elements may be exaggerated for ease of description and for clarity.

Terms of “first”, “second”, and the like may be used to describe various components, but the components should not be limited by these terms. These terms are used only for the purpose of distinguishing one component from another component. For example, without departing from the scope of the disclosure, a first component may be referred to as a second component, and similarly, a second component may also be referred to as a first component.

In the following description, the singular expressions include plural expressions unless the context clearly dictates otherwise. For example, as used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

In addition, a case where a portion of a layer, a film, an area, a plate, or the like is referred to as being “on” another portion, it includes not only a case where the portion is “directly on” another portion, but also a case where there is further another portion between the portion and another portion. In addition, in the specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion.

The phrase “in a plan view” means viewing the object from the top, and the phrase “in a schematic cross-sectional view” means viewing a cross-section of which the object is vertically cut from the side.

In the specification, in a case where a component (for example, ‘a first component’) is “operatively or communicatively coupled with/to” or “connected to” another component (for example, ‘a second component’), it should be understood that the component may be directly connected to the other component, or may be connected to the other component through another component (for example, a ‘third component’). In contrast, where a component (for example, ‘a first component’) is “directly coupled with/to” or “directly connected” to another component (for example, ‘a second component’), the case may be understood that another component (for example, ‘a third component’) is not present between the component and the other component.

It will be understood that the terms “connected to” or “coupled to” may include a physical or electrical connection or coupling.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the disclosure and others necessary for those skilled in the art to understand the disclosure will be described in detail with reference to the accompanying drawings.

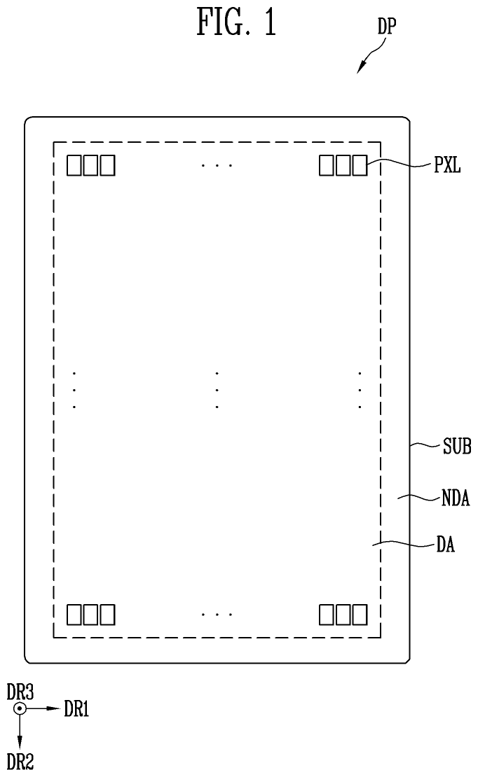

FIG. 1 is a schematic plan view schematically illustrating a display device according to embodiments of the disclosure. For convenience, in FIG. 1, a structure of the display panel DP is briefly shown based on a display area DA. However, according to an embodiment, at least one driving circuit unit, lines, and/or pads, which are/is not shown may be further provided on a display panel DP.

Referring to FIG. 1, the display device may include the display panel DP. In case that the display device is a display device in which a display surface is applied to at least one surface or a surface, such as a smartphone, a television, a tablet PC, a mobile phone, a video phone, an e-book reader, a desktop PC, a laptop PC, a netbook computer, a workstation, a server, a PDA, a portable multimedia player (PMP), an MP3 player, a medical device, a camera, an automotive display (or vehicle display), a transparent display, or a wearable display (for example, glass glasses, and a smart watches), the disclosure may be applied to the display device.

The display panel DP may have various shapes. For example, the display panel DP may be provided in a rectangular plate shape, but is not limited thereto. For example, the display panel DP may have a circular shape, an elliptical shape, or the like within the spirit and the scope of the disclosure. The display panel DP may include an angled corner and/or a curved corner. For convenience of description, in FIG. 1, a case where the display panel DP is a rectangular shape having a pair of long sides and a pair of short sides is shown, an extension direction of the long side is indicated as a second direction DR2, an extension direction of the short side is indicated as a first direction DR1, and a direction perpendicular to the extension directions of the long side and the short side is indicated as a third direction DR3. It is to be understood that the shapes disclosed herein may include shapes substantially identical or similar to the shapes.

The display panel DP may display an image. As the display panel DP, an organic light emitting display panel (OLED panel) using an organic light emitting diode as a light emitting element, an inorganic light emitting display panel using an inorganic light emitting diode as a light emitting element, an ultra-small light emitting diode display panel (a micro-scale LED display panel or a nano-scale LED display panel) using a small light emitting diode as small as a micro-scale (or nano-scale) as a light emitting element, and a display panel capable of self-luminescence, such as a quantum dot light emitting display panel (QD LED panel) using a quantum dot and an inorganic light emitting diode may be used. As the display panel DP, a non-luminous display panel such as a liquid crystal display panel (LCD panel), an electrophoretic display panel (EPD panel), and an electro-wetting display panel (EWD panel) may be used.

The display panel DP and a substrate SUB for forming the display panel DP may include a display area DA for displaying an image and a non-display area NDA except for the display area DA. The display area DA may form a screen on which the image is displayed, and the non-display area NDA may be a remaining area except for the display area DA. According to an embodiment, a shape of the display area DA and a shape of the non-display area NDA may be relatively designed.

Pixels PXL may be disposed in the display area DA on the substrate SUB. For example, the display area DA may include pixel areas in which each pixel PXL may be disposed.

The non-display area NDA may be disposed around the display area DA. Various lines, pads, and/or built-in circuits connected to the pixel PXL of the display area DA may be disposed in the non-display area NDA.

The display panel DP may include the substrate SUB (or a base layer) and the pixels PXL. The pixels PXL may be provided or disposed on the substrate SUB.

The substrate SUB may be formed of an insulating material such as glass or resin. The substrate SUB may be formed of a material having flexibility to be bent or folded, and may have a single-layer structure or a multi-layer structure. For example, the material having flexibility may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, the material forming the substrate SUB is not limited to the above-described embodiments.

Each of the pixels PXL may be a minimum unit for displaying an image. The pixels PXL may include a light emitting element emitting white light and/or color light. Each of the pixels PXL may emit light of any one color among red, green, and blue, but is not limited thereto, and may emit light of cyan, magenta, yellow, or the like within the spirit and the scope of the disclosure. The light emitting element may be, for example, an inorganic light emitting diode including an inorganic light emitting material. However, the light emitting element is not limited thereto, and for example, the light emitting element may be an organic light emitting diode.

The pixels PXL may be arranged or disposed in a matrix form along a row extending in the first direction DR1 and a column extending in the second direction DR2 crossing or intersecting the first direction DR1. However, an arrangement form of the pixels PXL is not particularly limited, and the pixels PXL may be arranged or disposed in various forms. The pixels PXL have a rectangular shape in the drawing, but the disclosure is not limited thereto, and the pixels PXL may be modified into various shapes. In case that pixels PXL are provided, the pixels PXL may be provided to have different areas (or sizes). For example, in a case of pixels PXL having different colors of emitted light, the pixels PXL may be provided in different areas (or sizes) or in different shapes for each color.

The pixel PXL may have a structure according to at least one of the embodiments to be described below. For example, each pixel PXL may have a structure to which any one of the embodiments to be described later is applied, or a structure to which at least two embodiments are applied in combination.

The pixel PXL may be formed as an active pixel, but is not limited thereto. For example, the pixel PXL may be formed as a pixel of a passive or active light emitting display device of various structures and/or driving methods.

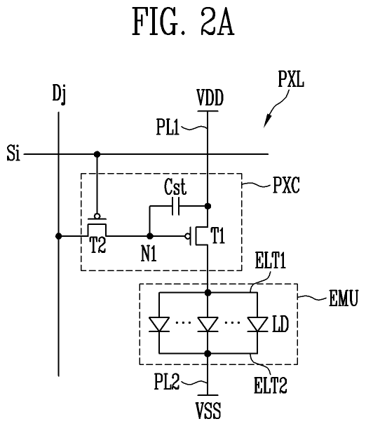

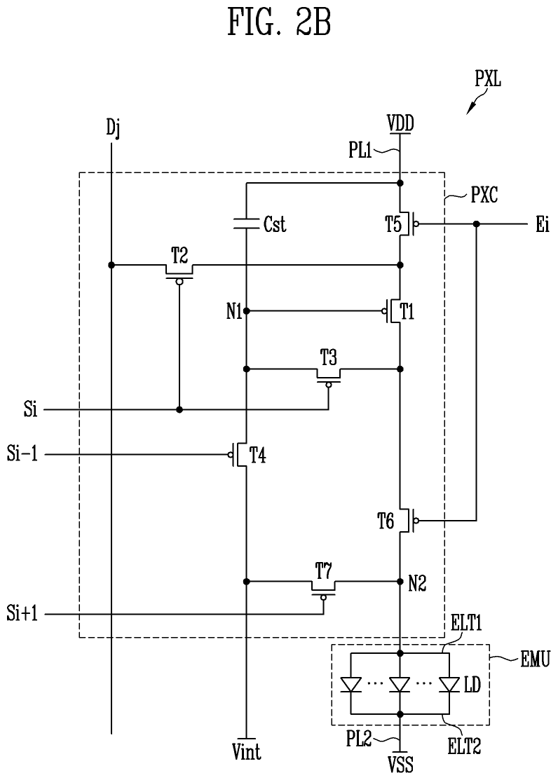

FIGS. 2A and 2B are circuit diagrams illustrating an electrical connection relationship between components included in the pixel included in the display device of FIG. 1 according to an embodiment. FIGS. 2A and 2B show an electrical connection relationship between the components included in the pixel PXL that may be applied to an active display device according to different embodiments. However, types of the components included in the pixel PXL to which the embodiment of the disclosure may be applied are not limited thereto.

In FIGS. 2A and 2B, not only the components included in each pixel PXL shown in FIG. 1, but also areas in which the components are provided are collectively referred to as the pixel PXL. According to an embodiment, each pixel PXL shown in FIGS. 2A and 2B may be any one of the pixels PXL included in the display device of FIG. 1, and the pixels PXL may have structures substantially the same or similar to each other.

Referring to FIGS. 1, 2A, and 2B, the pixel PXL may include a light emitting unit EMU that generates light of a luminance corresponding to a data signal. The pixel PXL may selectively further include a pixel driving circuit PXC (or a pixel circuit) for driving the light emitting unit EMU.

According to an embodiment, the light emitting unit EMU may include at least one light emitting element LD connected in parallel between a first power line PL1 to which a voltage of first driving power VDD is applied and a second power line PL2 to which a voltage of second driving power VSS is applied. For example, the light emitting unit EMU may include a first electrode ELT1 electrically connected to the first driving power VDD via the pixel driving circuit PXC and the first power line PL1, a second electrode ELT2 electrically connected to the second driving power VSS through the second power line PL2, and light emitting elements LD connected in parallel in the same direction between the first and second electrodes ELT1 and ELT2. In an embodiment, the first electrode ELT1 may be an anode electrode, and the second electrode ELT2 may be a cathode electrode.

In an embodiment, each of the light emitting elements LD included in the light emitting unit EMU may include a first end connected to the first driving power VDD through the first electrode ELT1, and a second end connected to the second driving power VSS through the second electrode ELT2. The first driving power VDD and the second driving power VSS may have different potentials. For example, the first driving power VDD may be set as a high potential power, and the second driving power VSS may be set as a low potential power. At this time, a potential difference between the first and second driving power VDD and VSS may be set to be equal to or greater than a threshold voltage of the light emitting element LD during an emission period of the pixel PXL.

As described above, each light emitting element LD connected in parallel in the same direction (for example, a forward direction) between the first electrode ELT1 and the second electrode ELT2 to which voltages of different potentials are respectively supplied may form each effective light source. Such effective light sources may be gathered to form the light emitting unit EMU of the pixel PXL.

The light emitting elements LD of the light emitting unit EMU may emit light with a luminance corresponding to a driving current supplied through the corresponding pixel driving circuit PXC. For example, during each frame period, the pixel driving circuit PXC may supply a driving current corresponding to a grayscale value of the corresponding frame data to the light emitting unit EMU. The driving current supplied to the light emitting unit EMU may be divided and may flow through the light emitting elements LD connected in the same direction. Accordingly, each light emitting element LD may emit light with a luminance corresponding to the current flowing therethrough, and thus the light emitting unit EMU may emit light with a luminance corresponding to the driving current.

The pixel driving circuit PXC may be connected to a scan line and a data line of the corresponding pixel PXL. For example, in case that it is assumed that the pixel PXL is disposed in an i-th (i is a positive integer) row and a j-th (j is a positive integer) column of the display area DA, the pixel driving circuit PXC of the pixel PXL may be connected to an i-th scan line Si and a j-th data line Dj. According to an embodiment, the pixel driving circuit PXC may be formed as in an embodiment shown in FIG. 2A.

Referring to FIG. 2A, the pixel driving circuit PXC may include first and second transistors T1 and T2 and a storage capacitor Cst.

A first terminal of the first transistor (driving transistor) T1 may be connected to the first driving power VDD, and a second terminal may be electrically connected to the light emitting element LD. A gate electrode of the first transistor T1 may be connected to a first node N1. The first transistor T1 controls an amount of the driving current supplied to the light emitting element LD in response to a voltage of the first node N1.

A first terminal of the second transistor T2 (switching transistor) may be connected to the j-th data line Dj, and a second terminal may be connected to the first node N1. Here, the first terminal and the second terminal of the second transistor T2 are different terminals. For example, in case that the first terminal may be a source electrode, the second terminal may be a drain electrode. A gate electrode of the second transistor T2 may be connected to the i-th scan line Si.

The second transistor T2 may be turned on in case that a scan signal of a voltage (for example, a low voltage) capable of turning on the second transistor T2 is supplied from the i-th scan line Si, to electrically connect the j-th data line Dj and the first node N1. At this time, the data signal of the corresponding frame is supplied to the j-th data line Dj, and thus the data signal is transmitted to the first node N1. The data signal transmitted to the first node N1 is stored into the storage capacitor Cst.

One electrode of the storage capacitor Cst may be connected to the first driving power VDD, and another electrode may be connected to the first node N1. The storage capacitor Cst charges a voltage corresponding to the data signal supplied to the first node N1 and maintains the charged voltage until a data signal of a next frame is supplied.

The pixel driving circuit PXC is not limited to FIG. 2A, and a structure of the pixel driving circuit PXC may be variously changed. For example, the pixel driving circuit PXC may further include at least one transistor element such as a transistor element for compensating for a threshold voltage of the first transistor T1, a transistor element for initializing the first node N1, and/or a transistor element for controlling an emission time of the light emitting elements LD, other circuit elements such as a boosting capacitor for boosting the voltage of the first node N1, or the like within the spirit and the scope of the disclosure.

In FIG. 2A, all transistors included in the pixel driving circuit PXC, for example, the first and second transistors T1 and T2 are P-type transistors, but the disclosure is not limited thereto. For example, at least one of the first and second transistors T1 and T2 included in the pixel driving circuit PXC may be changed to an N-type transistor. A connection position of some or a number of components may be changed due to the change of the transistor type. For example, the storage capacitor Cst may be connected between the gate electrode and the second terminal of the first transistor T1, or the light emitting unit EMU may be connected between the first driving power VDD and the pixel driving circuit PXC.

According to an embodiment, the pixel driving circuit PXC may be formed as in an embodiment shown in FIG. 2B.

Referring to FIG. 2B, the pixel driving circuit PXC may be further connected to at least one other scan line. For example, the pixel PXL disposed in the i-th row of the display area DA may be further connected to an (i−1)-th scan line Si−1 and/or an (i+1)-th scan line Si+1. According to an embodiment, the pixel driving circuit PXC may be further connected to third power in addition to the first and second driving power VDD and VSS. For example, the pixel driving circuit PXC may also be connected to an initialization power Vint.

The pixel driving circuit PXC may include first to seventh transistors T1 to T7 and a storage capacitor Cst.

A first terminal, for example, a source electrode, of the first transistor T1 (driving transistor) may be connected to the first driving power VDD via the fifth transistor T5, and a second terminal, for example, a drain electrode may be connected to the first end of the light emitting elements LD via the sixth transistor T6. A gate electrode of the first transistor T1 may be connected to a first node N1. The first transistor T1 controls a driving current flowing between the first driving power VDD and the second driving power VSS via the light emitting elements LD in response to a voltage of the first node N1.

The second transistor T2 (switching transistor) may be connected between the j-th data line Dj connected to the pixel PXL and the source electrode of the first transistor T1. A gate electrode of the second transistor T2 may be connected to the i-th scan line Si connected to the pixel PXL. The second transistor T2 may be turned on in case that a scan signal of a gate-on voltage (for example, a low voltage) is supplied from the i-th scan line Si, to electrically connect the j-th data line Dj to the source electrode of the first transistor T1. Therefore, in case that the second transistor T2 is turned on, the data signal supplied from the j-th data line Dj is transmitted to the first transistor T1.

The third transistor T3 may be connected between the drain electrode of the first transistor T1 and the first node N1. A gate electrode of the third transistor T3 may be connected to the i-th scan line Si. The third transistor T3 may be turned on in case that a scan signal of a gate-on voltage is supplied from the i-th scan line Si, to electrically connect the drain electrode of the first transistor T1 and the first node N1.

The fourth transistor T4 may be connected between the first node N1 and an initialization power line to which the initialization power Vint is applied. A gate electrode of the fourth transistor T4 may be connected to a previous scan line, for example, an (i−1)-th scan line Si−1. The fourth transistor T4 may be turned on in case that a scan signal of a gate-on voltage is supplied to the (i−1)-th scan line Si−1, to transmit a voltage of the initialization power Vint to the first node N1. Here, the initialization power Vint may have a voltage level lower than the lowest voltage level of the data signal.

The fifth transistor T5 may be connected between the first driving power VDD and the first transistor T1. A gate electrode of the fifth transistor T5 may be connected to a corresponding emission control line, for example, an i-th emission control line Ei. The sixth transistor T6 may be connected between the first transistor T1 and the first end (or a second node N2) of the light emitting elements LD. A gate electrode of the sixth transistor T6 may be connected to the i-th emission control line Ei. The fifth and sixth transistors T5 and T6 may be turned off in case that an emission control signal of a gate-off voltage is supplied to the i-th emission control line Ei, and may be turned on in other cases.

The seventh transistor T7 may be connected between the first end of the light emitting elements LD and the initialization power line. A gate electrode of the seventh transistor T7 may be connected to any one of scan lines of a next stage, for example, an (i+1)-th scan line Si+1. The seventh transistor T7 may be turned on in case that a scan signal of a gate-on voltage is supplied to the (i+1)-th scan line Si+1, to supply the voltage of the initialization power Vint to the first end of the light emitting elements LD.

The storage capacitor Cst may be connected between the first driving power VDD and the first node N1. The storage capacitor Cst may store a data signal supplied to the first node N1 and a voltage corresponding to the threshold voltage of the first transistor T1 in each frame period.

In FIG. 2B, all transistors included in the pixel driving circuit PXC, for example, the first to seventh transistors T1 to T7 are P-type transistors, but the disclosure is not limited thereto. For example, at least one of the first to seventh transistors T1 to T7 may be changed to an N-type transistor.

The structure of the pixel PXL applicable to the disclosure is not limited to the embodiments shown in FIGS. 2A and 2B, and the corresponding pixel PXL may have various structures. In an embodiment, each pixel PXL may be formed inside of a passive light emitting display device or the like within the spirit and the scope of the disclosure. The pixel driving circuit PXC may be omitted, and both ends of the light emitting elements LD included in the light emitting unit EMU may be connected to or directly connected to each of the scan lines Si−1, Si, and Si+1, the j-th data line Dj, the first power line PL1 to which the first driving power VDD is applied, the second power line PL2 to which the second driving power VSS is applied, a control line, and/or the like within the spirit and the scope of the disclosure.

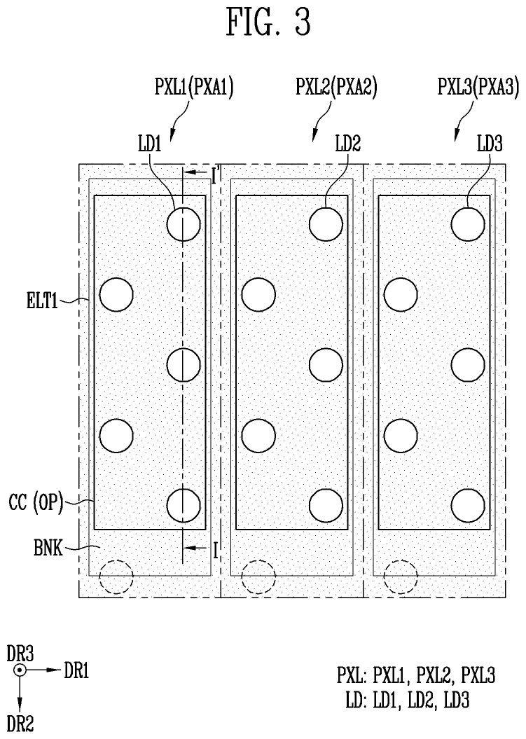

FIG. 3 schematically illustrates the pixel included in the display device of FIG. 1, and is a schematic plan view of the pixel viewed from an upper portion based on the light emitting unit shown in FIGS. 2A and 2B.

Referring to FIGS. 1 and 3, the display panel DP may include a first pixel PXL1 (or a first pixel area PXA1), a second pixel PXL2 (or a second pixel area PXA2), and a third pixel PXL3 (or a third pixel area PXA3). The first pixel PXL1, the second pixel PXL2, and the third pixel PXL3 may form one unit pixel.

According to an embodiment, the first, second, and third pixels PXL1, PXL2, and PXL3 may emit light in different colors. For example, the first pixel PXL1 may be a red pixel emitting light in red, the second pixel PXL2 may be a green pixel emitting light in green, and the third pixel PXL3 may be a blue pixel emitting light in blue. However, the color, type, and/or number of pixels forming the unit pixel are/is not particularly limited, and, for example, the color of light emitted by each pixel may be variously changed. According to an embodiment, the first, second, and third pixels PXL1, PXL2, and PXL3 may emit light in the same color. For example, the first, second, and third pixels PXL1, PXL2, and PXL3 may be blue pixels emitting light in blue.

Since the first pixel PXL1, the second pixel PXL2, and the third pixel PXL3 are substantially the same or similar to each other, hereinafter, the first pixel PXL1 is described by including the first pixel PXL1, the second pixel PXL2, and the third pixel PXL3.

The first pixel PXL1 may include the first electrode ELT1, a bank BNK, and the light emitting elements LD (or first light emitting elements LD1).

The first electrode ELT1 may be positioned at a center of the first pixel area PXA1. The first electrode ELT1 may be spaced apart from and electrically separated from the first electrode ELT1 of another pixel.

The first electrode ELT1 may guide the light emitted from the light emitting elements LD in the third direction DR3. To this end, the first electrode ELT1 may be formed of a conductive material (or substance) having a constant reflectance. The conductive material (or substance) may include an opaque metal. The opaque metal may include, for example, a metal such as silver (Ag), magnesium (Mg), aluminum (Al), platinum (Pt), palladium (Pd), gold (Au), nickel (Ni), neodymium (Nd), iridium (Ir), chromium (Cr), titanium (Ti), molybdenum (Mo), copper (Cu), and an alloy thereof.

In embodiments, the first electrode ELT1 may have a multi-layer structure including electrode layers. The first electrode ELT1 may include a first electrode layer and a second electrode layer sequentially stacked in the third direction DR3, and one of the first electrode layer and the second electrode layer may have a relatively high electrical conductivity (or conductivity), the other of the first electrode layer and the second electrode layer may have a relatively large reflectance. For example, the first electrode layer may be formed of a low-resistance material to reduce a resistance (or a contact resistance), and the second electrode layer may include a material having a constant reflectance to allow the light emitted from the light emitting elements LD to proceed in the third direction DR3. For example, the first electrode layer may include a metal such as molybdenum (Mo), titanium (Ti), copper (Cu), aluminum (Al), silver (Ag), and an alloy thereof. For example, the second electrode layer may include a metal such as copper (Cu), silver (Ag), magnesium (Mg), aluminum (Al), platinum (Pt), palladium (Pd), gold (Au), nickel (Ni), neodymium (Nd), iridium (Ir), chromium (Cr), titanium (Ti), and an alloy thereof, and may include a metal having a reflectance greater than that of the first electrode layer.

According to an embodiment, the first electrode ELT1 may include a transparent conductive material (or substance). The transparent conductive material (or substance) may include a conductive oxide such as indium tin oxide (ITO), indium zinc oxide (IZO), zinc oxide (ZnO), indium gallium zinc oxide (IGZO), indium tin zinc oxide (ITZO), a conductive polymer such as poly(3,4-ethylenedioxythiophene) (PEDOT), and the like within the spirit and the scope of the disclosure.

The bank BNK (or a bank pattern, a light blocking layer, or a light blocking pattern) may be positioned in the first pixel area PXA1. The bank BNK may be entirely disposed in the first pixel area PXA1 and may cover or overlap the first electrode ELT1. The bank BNK may cover or overlap most of the first electrode ELT1 except for an area overlapping the light emitting elements LD in the third direction DR3.

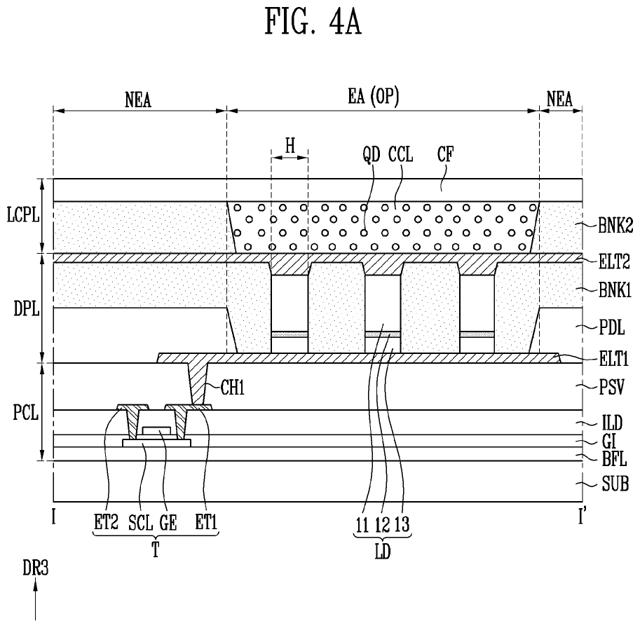

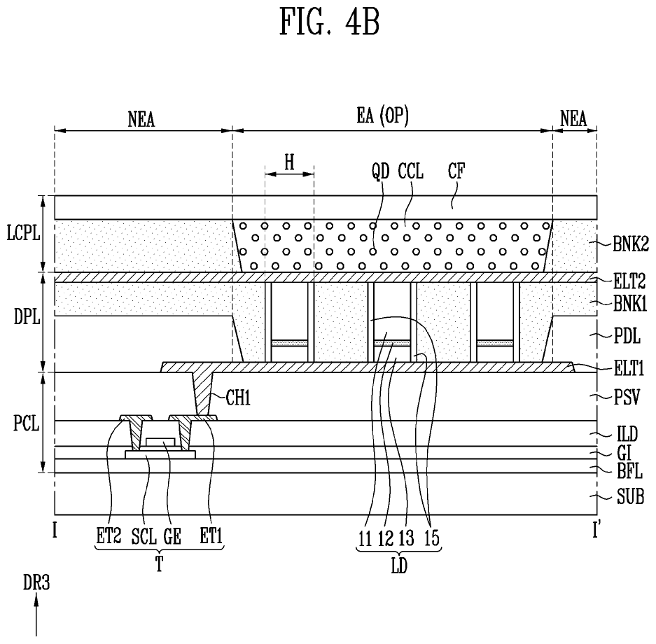

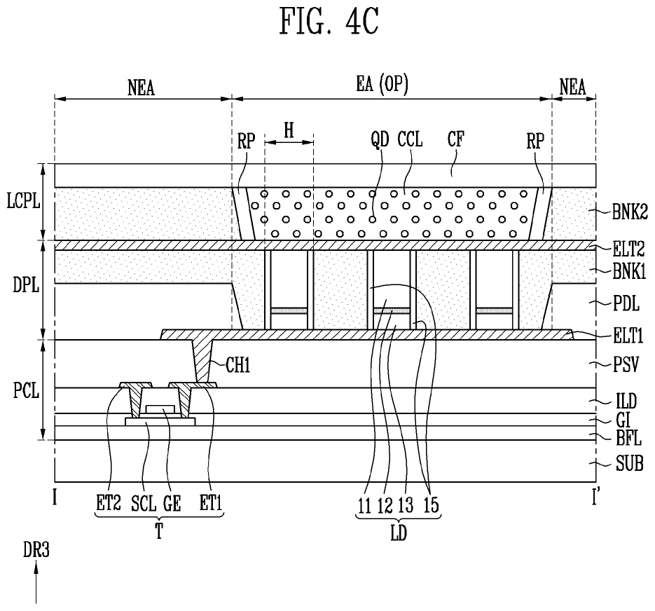

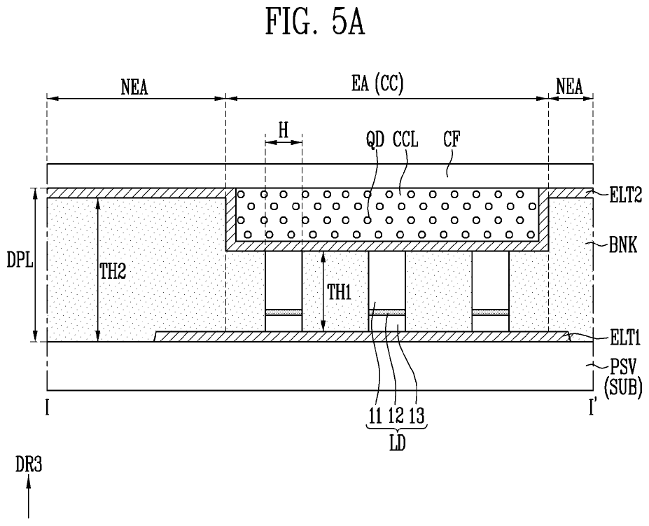

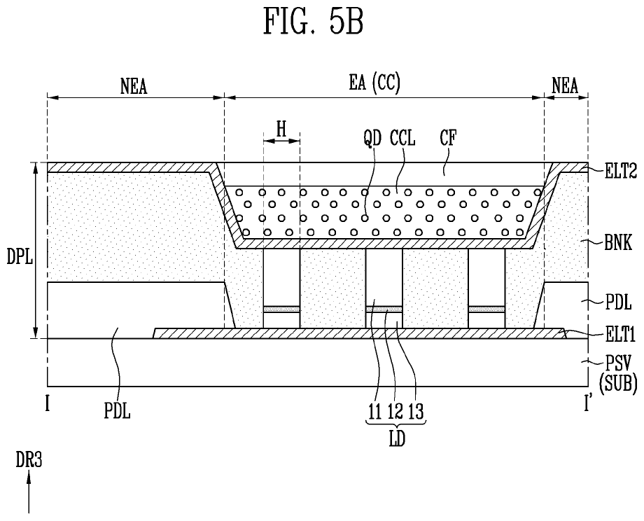

According to an embodiment, the bank BNK may include a concave portion (a recessed portion) CC or an opening OP (or an opening portion). The recessed portion CC may be a portion concave in a direction opposite to the third direction DR3 from a periphery (refer to FIG. 5A). The opening OP may pass through the bank BNK and may be a portion exposing a lower structure. As will be described later with reference to FIG. 4A, in case that the bank BNK may include two layers that are distinguished from each other, the opening OP may be formed in a relatively upper layer. An emission area may be defined (or partitioned) by the recessed portion CC or the opening OP of the bank BNK. As shown in FIG. 3, the recessed portion CC or the opening OP may be formed for each pixel PXL in correspondence with the first electrode ELT1.

The recessed portion CC may have a quadrangular planar shape in correspondence with a planar shape of the first electrode ELT1, but is not limited thereto. For example, the recessed portion CC may have various planar shapes, such as a circular shape or a polygonal shape.

Holes exposing the first electrode ELT1 may be formed in the recessed portion CC of the bank BNK. The light emitting elements LD may be disposed in the holes, respectively.

The bank BNK may include an insulating material including an inorganic material and/or an organic material. For example, the bank BNK may include at least one inorganic layer including various inorganic insulating materials including silicon nitride (SiNₓ) or silicon oxide (SiOₓ). For example, the bank BNK may be formed as an insulator of a single layer or multiple layers including at least one organic layer, photoresist layer, and/or the like including various organic insulating materials or including organic or inorganic materials in combination. For example, a material of the bank BNK may be variously changed.

In an embodiment, the bank BNK may include at least one light blocking material that blocks light. The bank BNK may prevent a light leakage defect in which light (or rays) leaks between the pixels PXL. The bank BNK may cover or overlap the first electrode ELT1 (for example, the first electrode ELT1 formed of a conductive material having a specific or given reflectance), to prevent light incident from the outside (for example, outside the display device) from being reflected by the first electrode ELT1. For example, the bank BNK may prevent deterioration of display quality due to reflection of external light (for example, deterioration of display quality of an image displayed on the display device).

According to an embodiment, the bank BNK may include a transparent material (or substance). The transparent material may include, for example, polyamides resin, polyimides resin, and the like within the spirit and the scope of the disclosure. In order to minimize the reflection of the external light by the first electrode ELT1, a light blocking material layer may be separately provided and/or formed on the bank BNK.

In an embodiment, the bank BNK may include a metal oxide or a metal oxide layer. For example, the bank BNK may include a metal such as copper (Cu), iron (Fe), or zinc (Zn). The bank BNK may include a metal oxide layer formed by oxidizing the metal. The metal oxide layer formed using the metal such as copper (Cu), iron (Fe), or zinc (Zn) may have a black color and may function as a black matrix. According to an embodiment, the metal oxide layer may be formed only on an upper surface of the bank BNK or may form the entire bank BNK.

The light emitting elements LD may be provided on the first electrode ELT1, and the light emitting elements LD may be respectively disposed in the holes formed in the recessed portion CC of the bank BNK. First light emitting elements LD1 may be provided to the first pixel PXL1, second light emitting elements LD2 may be provided to the second pixel PXL2, and third light emitting elements LD3 may be provided to the third pixel PXL3. One light emitting element LD may be disposed in one hole. The bank BNK may be disposed between the light emitting element LD and an adjacent light emitting element LD, and the bank BNK may surround the light emitting element LD. The bank BNK may cover or overlap the first electrode ELT1 between the light emitting element LD and the adjacent light emitting element LD, and the bank BNK may prevent the reflection of the external light by the first electrode ELT1. The bank BNK may prevent the light emitted from the light emitting element LD from proceeding to an area corresponding to the adjacent light emitting element LD or an adjacent pixel PXL. Since light does not flow from the adjacent pixel PXL, the pixel PXL may emit light with a desired luminance.

As described above, the bank BNK may be disposed in a form surrounding the light emitting element LD and may cover or overlap most of the first electrode ELT1. The bank BNK may include a light blocking material such as a black matrix or a metal oxide layer. Therefore, the bank BNK may minimize the reflection of the external light by the first electrode ELT1 and may prevent the light emitted from the light emitting element LD from proceeding to the adjacent light emitting element LD or the adjacent pixel PXL. For example, the bank BNK may minimize the reflection of the external light and prevent color mixing or interference of light emitted from adjacent pixels PXL, thereby preventing deterioration of display quality of the image displayed on the display device.

FIGS. 4A, 4B, and 4C are schematic cross-sectional views illustrating an embodiment of a pixel taken along line I-I′ of FIG. 3. FIGS. 4A, 4B, and 4C are examples of circuit elements that may be disposed in a pixel circuit layer PCL, and show an arbitrary transistor T (for example, the first transistor T1 of FIG. 2A or the sixth transistor T6 of FIG. 2B).

In FIGS. 4A, 4B, and 4C, one pixel is shown in a simplified manner, such as showing an electrode as a single-layer electrode and insulating layers as only a single-layer insulating layer, but the disclosure is limited thereto.

In an embodiment, unless otherwise specified, “formed and/or provided on the same layer” may mean formed in the same process, and “formed and/or provided on different layers” may mean formed in different processes.

Referring to FIGS. 1, 3, 4A, 4B, and 4C, the pixel circuit layer PCL and a display element layer DPL (or a light emitting element layer) may be sequentially disposed on the substrate SUB. A light conversion pattern layer LCPL may be further disposed on the display element layer DPL. According to an embodiment, the pixel circuit layer PCL, the display element layer DPL, and the light conversion pattern layer LCPL may be formed entirely in the display area DA of the display panel DP (refer to FIG. 1).

The pixel circuit layer PCL may include a buffer layer BFL, a transistor T, and a protective layer PSV. As shown in FIGS. 4A, 4B, and 4C, the buffer layer BFL, the transistor T, and the protective layer PSV may be sequentially stacked each other on the substrate SUB.

The buffer layer BFL may prevent an impurity from diffusing into the transistor T. The buffer layer BFL may be an inorganic insulating layer including an inorganic material. The inorganic insulating layer may include, for example, silicon nitride (SiNₓ), silicon oxide (SiOₓ), silicon oxynitride (SiOₓN_{y}), or may include at least one of a metal oxide such as aluminum oxide (AlOₓ). The buffer layer BFL may be provided as a single layer, or may be provided as a multilayer of at least a double layer. In case that the buffer layer BFL is provided as a multilayer, each layer may be formed of a same material or a similar material or different materials. The buffer layer BFL may be omitted according to a material and a process condition of the substrate SUB.

The transistor T may be the first transistor T1 of FIG. 2A or the sixth transistor T6 of FIG. 2B. A structure of each of the second transistor T2 shown in FIG. 2A and the first to seventh transistors T1 to T7 shown in FIG. 2B may be substantially the same as or similar to a structure of the transistor T.

The transistor T may include a semiconductor pattern SCL, a gate electrode GE, a first terminal ET1 (or a first transistor electrode), and a second terminal ET2 (or a second transistor electrode). The first terminal ET1 may be one of a source electrode and a drain electrode, and the second terminal ET2 may be the other electrode. For example, in case that the first terminal ET1 is the drain electrode, the second terminal ET2 may be the source electrode.

The semiconductor pattern SCL may be provided and/or formed on the buffer layer BFL. The semiconductor pattern SCL may include a first contact region contacting the first terminal ET1 and a second contact region contacting the second terminal ET2. A region between the first contact region and the second contact region may be a channel region. The channel region may overlap the gate electrode GE of the corresponding transistor T. The semiconductor pattern SCL may be a semiconductor pattern formed of amorphous silicon, polysilicon (e.g., low-temperature polysilicon), an oxide semiconductor, an organic semiconductor, or the like within the spirit and the scope of the disclosure. The channel region is, for example, a semiconductor pattern that is not doped with an impurity, and may be an intrinsic semiconductor. The first contact region and the second contact region may be semiconductor patterns doped with an impurity.

The gate insulating layer GI may be provided and/or formed on the semiconductor pattern SCL. The gate insulating layer GI may be an inorganic insulating layer including an inorganic material. For example, the gate insulating layer GI may include a same material or a similar material as the buffer layer BFL, or may include one or more materials selected from the materials of the buffer layer BFL. According to an embodiment, the gate insulating layer GI may be formed of an organic insulating layer including an organic material. The gate insulating layer GI may be provided as a single layer, but may also be provided as a multilayer of at least a double layer.

The gate electrode GE may be provided and/or formed on the gate insulating layer GI to correspond to the channel region of the semiconductor pattern SCL. The gate electrode GE may be provided on the gate insulating layer GI and may overlap the channel region of the semiconductor pattern SCL. The gate electrode GE may be formed in a single layer of a material selected from a group consisting of copper (Cu), molybdenum (Mo), tungsten (W), neodymium (Nd), titanium (Ti), aluminum (Al), silver (Ag), and an alloy thereof alone or a mixture thereof, or may be formed in a double layer or multi-layer structure of a molybdenum (Mo), titanium (Ti), copper (Cu), aluminum (Al) or silver (Ag), which is a low-resistance material, to reduce a line resistance.

An interlayer insulating layer ILD may be provided and/or formed on the gate electrode GE. The interlayer insulating layer ILD may include a same material or a similar material as the gate insulating layer GI, or may include one or more materials selected from materials of the gate insulating layer GI.

Each of the first terminal ET1 and the second terminal ET2 may be provided and/or formed on the interlayer insulating layer ILD, and may contact the first contact region and the second contact region of the semiconductor pattern SCL through a contact hole passing through the interlayer insulating layer ILD (and the gate insulating layer GI). Each of the first and second terminals ET1 and ET2 may include a same material or a similar material as the gate electrode GE, or may include one or more materials selected from materials of the gate electrode GE.

In the above-described embodiment, the first and second terminals ET1 and ET2 of the transistor T are separate electrodes electrically connected to the semiconductor pattern SCL through the contact hole sequentially passing through the interlayer insulating layer ILD and the gate insulating layer GI, but the disclosure is not limited thereto. According to an embodiment, the first terminal ET1 of the transistor T may be a first contact region adjacent to the channel region of the corresponding semiconductor pattern SCL, and the second terminal ET2 of the transistor T may be a second contact region adjacent to the channel region of the corresponding semiconductor pattern SCL. The first terminal ET1 of the transistor T may be electrically connected to the light emitting element LD through a separate connection means such as a bridge electrode.

Although a case where the transistor T is a thin film transistor having a top gate structure has been described as an example with reference to FIGS. 4A, 4B, and 4C, the disclosure is not limited thereto, and the structure of the transistor T may be variously changed. For example, the transistor T may have a bottom gate structure, a dual gate structure, or a double gate structure.

The protective layer PSV may be provided and/or formed on the transistor T.

The protective layer PSV may be provided in a form including an organic insulating layer, an inorganic insulating layer, or an organic insulating layer disposed on an inorganic insulating layer. The inorganic insulating layer may include, for example, silicon oxide (SiOₓ), silicon nitride (SiNₓ), silicon oxynitride (SiOₓN_{y}), or may include at least one of a metal oxide such as aluminum oxide (AlOₓ). The organic insulating layer may include, for example, at least one of acrylic resin (polyacrylates resin), epoxy resin, phenolic resin, polyamides resin, polyimide resin, unsaturated polyesters resin, poly-phenylen ethers resin, poly-phenylene sulfides resin, and benzocyclobutene resin.

The protective layer PSV may include a first contact hole CH1 exposing the first terminal ET1 of the transistor T.

The display element layer DPL may be provided on the protective layer PSV.

The display element layer DPL may include the first electrode ELT1, the pixel defining layer PDL, the light emitting element LD (or light emitting elements), a first bank BNK1 (a planarization layer, a first light blocking layer, or a first blocking pattern), and the second electrode ELT2. The first electrode ELT1, the pixel defining layer PDL, the light emitting element LD, the first bank BNK1, and the second electrode ELT2 may be sequentially disposed or formed on the protective layer PSV (or the pixel circuit layer PCL).

The first electrode ELT1 may be disposed or formed on the protective layer PSV. The first electrode ELT1 may be disposed to correspond to an emission area EA of each pixel PXL. Here, the emission area EA may be an area in which light is output or emitted. A non-emission area NEA may be a remaining area except for the emission area EA, and the non-emission area NEA may be an area in which light is not emitted. The non-emission area NEA may be positioned between the pixels PXL to surround the emission area EA in a plan view.

In an embodiment, the first electrode ELT1 may be an anode electrode. Since the first electrode ELT1 is substantially the same as or similar to the first electrode ELT1 described with reference to FIG. 3, a description of the first electrode ELT1 is omitted.

The first electrode ELT1 may contact the first terminal ET1 of the transistor T through the first contact hole CH1.

According to an embodiment, the first electrode ELT1 may include a material for bonding to the light emitting element LD. For example, the first electrode ELT1 may include copper (Cu).

The pixel defining layer PDL may be disposed or formed on the protective layer PSV and the first electrode ELT1 in the non-emission area NEA. The pixel defining layer PDL may partially overlap an edge of the first electrode ELT1 in the non-emission area NEA. The pixel defining layer PDL may be formed between the pixels PXL to surround the emission area EA to define (or partition) the emission area EA of each pixel PXL. An opening of the pixel defining layer PDL may correspond to the emission area EA. In a step of disposing the light emitting elements LD, the pixel defining layer PDL may prevent disposition of the light emitting elements LD (for example, light emitting elements shown by a dotted line in FIG. 3) in the non-emission area NEA. The pixel defining layer PDL may prevent a defect (for example, a short-circuit) that occurs in case that the light emitting elements LD disposed in the non-emission area NEA are connected to another configuration (for example, the first electrode ELT1).

The pixel defining layer PDL may include an insulating material including an inorganic material and/or an organic material. For example, the pixel defining layer PDL may include at least one inorganic layer including various inorganic insulating materials including silicon nitride (SiNₓ) or silicon oxide (SiOₓ). For example, the pixel defining layer PDL may be formed as an insulator of a single layer or multiple layers including at least one organic layer, photoresist layer, and/or the like including various organic insulating materials or including organic or inorganic materials in combination. For example, a material of the pixel defining layer PDL may be variously changed.

According to an embodiment, the pixel defining layer PDL may include a same material or a similar material as the first bank BNK1. The pixel defining layer PDL may not be distinguished from the first bank BNK1 disposed on the pixel defining layer PDL. For example, the pixel defining layer PDL and the first bank BNK1 may be integral with each other.

The light emitting element LD may be disposed on the first electrode ELT1 in the emission area EA and may be positioned in the hole H of the first bank BNK1.

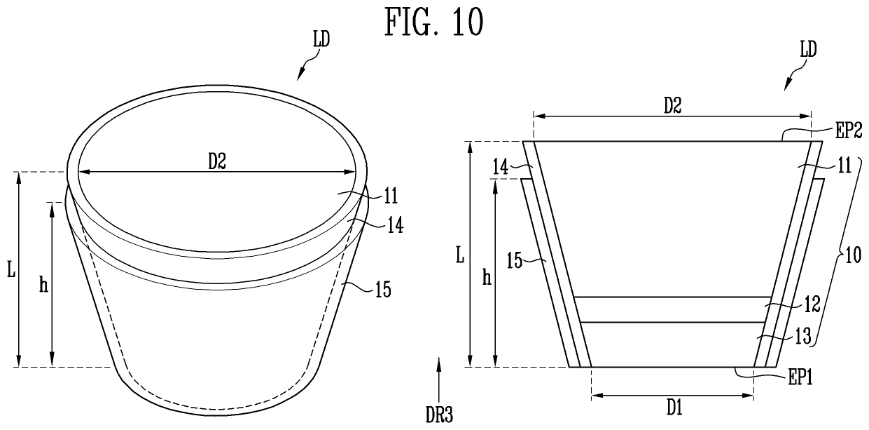

The light emitting element LD may include a second semiconductor layer 13 that is in contact with or electrically connected to the first electrode ELT1, an active layer 12 disposed on the second semiconductor layer 13, and a first semiconductor layer 11 disposed on the second electrode ELT2, and in contact with or electrically connected to the second electrode ELT2. An electron-hole pair is combined in the active layer 12, and thus the light emitting element LD may emit light. A specific or given configuration (for example, the first semiconductor layer 11, the active layer 12, and the second semiconductor layer 13) of the light emitting element LD is described later with reference to FIG. 10.

In an embodiment, as shown in FIG. 4B, the display element layer DPL may further include a first reflective member 15 (or a first reflective pattern) surrounding an outer circumferential surface between the first end and the second end of the light emitting element LD in the hole H of the first bank BNK1. Here, the first end may be a portion of the light emitting element LD in contact with the first electrode ELT1, and the second end may be another portion of the light emitting element LD in contact with the second electrode ELT2. The first reflective member 15 may be included in the light emitting element LD. For example, the first reflective member 15 may be formed in a manufacturing process of the light emitting element LD. The first semiconductor layer 11, the active layer 12, and the second semiconductor layer 13 of the light emitting element LD may be spaced apart from the first bank BNK1 by the first reflective member 15.

The first reflective member 15 may be formed of a material having a reflectance in order to focus the light emitted from the light emitting element LD to a specific or given area while allowing the light to proceed in the image display direction. For example, the first reflective member 15 may be formed of a conductive material (or substance) having a reflectance. The first reflective member 15 may include an opaque metal. The first reflective member 15 may include a same material or a similar material as the first electrode ELT1, or may include one or more materials selected from the materials of the first electrode ELT1. In case that the first reflective member 15 may include a conductive material, the first reflective member 15 may be disposed to be spaced apart from or electrically separated from at least one of the first electrode ELT1 and the second electrode ELT2 so that the first electrode ELT1 and the second electrode ELT2 are not electrically connected to each other by the first reflective member 15. For example, the first reflective member 15 may be disposed to surround only a portion of an outer circumferential surface of the light emitting element LD (refer to FIG. 10).

The first bank BNK1 may be provided or formed entirely on the substrate SUB to cover or overlap the pixel defining layer PDL, the first electrode ELT1, and the outer circumferential surfaces of the light emitting element LD. Since the first bank BNK1 is substantially the same as the bank BNK described with reference to FIG. 3 or is included in the bank BNK, a repetitive description is omitted. The second end (for example, the second end contacting the second electrode ELT2) of the light emitting element LD may be exposed by the hole H of the first bank BNK1.

The first bank BNK1 may include at least one black matrix material (for example, at least one light blocking material) among various types of black matrix materials, a color filter material of a specific or given color, and/or the like within the spirit and the scope of the disclosure. The first bank BNK1 may include a metal oxide or a metal oxide layer.

The first bank BNK1 may be provided in a form filling an empty space between the pixel defining layer PDL and the light emitting element LD and an empty space between the light emitting element LD and the adjacent light emitting element LD. The first bank BNK1 may contact a side surface (or the outer circumferential surface) of the light emitting element LD. The first bank BNK1 may prevent the side surface of the light emitting element LD from coming into contact with another conductive material (for example, the second electrode ELT2). The first bank BNK1 may cover or overlap the first electrode ELT1 to prevent an electrical short circuit between the first electrode ELT1 and the second electrode ELT2. The first bank BNK1 may cover or overlap the first electrode ELT1 to minimize the reflection of the external light by the first electrode ELT1.

In order to fill an empty space between the light emitting element LD and the adjacent light emitting element LD, the first bank BNK1 may include an insulating material including an organic material, but the first bank BNK1 is limited thereto. For example, in case that the first bank BNK1 may include a metal oxide, a metal for forming the first bank BNK1 may be applied using a metal ink, and thus the metal may be filled in the empty space between the light emitting element LD and the adjacent light emitting element LD.

In FIG. 4A, on the first electrode ELT1, a height (or an average height) of an upper surface of the first bank BNK1 (or a thickness of the first bank BNK1 in the third direction DR3) is greater than a length (or a thickness) of the light emitting element LD in the third direction DR3, but the first bank BNK1 is not limited thereto. For example, as shown in FIG. 4B, the height of the upper surface of the first bank BNK1 may be substantially the same as the length (or the thickness) of the light emitting element LD in the third direction DR3. As another example, the height of the upper surface of the first bank BNK1 may be less than the length (or the thickness) of the light emitting element LD in the third direction DR3.

The second electrode ELT2 (or a common electrode) may be provided and/or formed on the first bank BNK1 (and the light emitting element LD). As shown in FIG. 4A, the second electrode ELT2 may be connected to the first semiconductor layer 11 of the light emitting element LD through the hole H, or as shown in FIG. 4B, the second electrode ELT2 may be in direct contact with the first semiconductor layer 11 of the light emitting element LD.

The second electrode ELT2 may be provided or disposed in the non-emission area NEA, and the second electrode ELT2 may be provided entirely on the substrate SUB. The second electrode ELT2 may be a common layer commonly provided to the pixel PXL and pixels PXL adjacent thereto (for example, the first to third pixels PXL1 to PXL3 shown in FIG. 3). In an embodiment, the second electrode ELT2 may be a cathode electrode. The second electrode ELT2 may be connected to the second driving power VSS (refer to FIGS. 2A and 2B), and thus the voltage of the second driving power VSS may be transmitted to the second electrode ELT2.

The second electrode ELT2 may be formed of various transparent conductive materials (or substances) to allow the light emitted from the light emitting element LD to proceed in the third direction DR3 without loss. For example, the second electrode ELT2 may include at least one of various transparent conductive materials (or substances) including indium tin oxide (ITO), indium zinc oxide (IZO), zinc oxide (ZnO), indium gallium zinc oxide (IGZO), indium tin zinc oxide (ITZO), and the like, and may be formed to be substantially transparent or translucent to satisfy a light transmittance (or transmission). However, the material of the second electrode ELT2 is not limited to the above-described embodiment.

A light conversion pattern layer LCPL may be disposed on the display element layer DPL. The light conversion pattern layer LCPL may change a wavelength (or a color) of light emitted from the display element layer DPL by using quantum dot, and may selectively transmit light of a specific or given wavelength (or a specific or given color) by using a color filter. The light conversion pattern layer LCPL may be formed on a base surface provided by the display element layer DPL through a continuous process. However, the light conversion pattern layer LCPL is not limited thereto, and for example, the light conversion pattern layer LCPL may be formed on the display element layer DPL through an adhesion process using an adhesive layer.

The light conversion pattern layer LCPL may include a second bank BNK2 and a light conversion pattern, and the light conversion pattern may include a color conversion layer CCL (or a color conversion pattern) and a color filter CF.

The second bank BNK2 (a second bank pattern, a second light blocking layer, or a second light blocking pattern) may be positioned in the non-emission area NEA. Since the second bank BNK2 is substantially the same as the bank BNK described with reference to FIG. 3 or is included in the bank BNK, a repetitive description is omitted.

The second bank BNK2 may include at least one black matrix material (for example, at least one light blocking material) among various types of black matrix materials, a color filter material of a specific or given color, and/or the like within the spirit and the scope of the disclosure. The second bank BNK2 may include a metal oxide or a metal oxide layer. For example, the second bank BNK2 may include a light blocking material that prevents light leakage between the pixel PXL and pixels PXL adjacent to thereto. The second bank BNK2 may be a black matrix. The second bank BNK2 may prevent color mixing of light emitted from each of adjacent pixels PXL.

An opening OP may be formed in the second bank BNK2. The second bank BNK2 may be formed between the pixels PXL to surround the emission area EA in a plan view, and define (or partition) the emission area EA of each pixel PXL. The emission area EA may correspond to the opening OP of the second bank BNK2. The second bank BNK2 may be a dam structure that finally defines the emission area EA to which the color conversion layer CCL is to be supplied (or input) on the second electrode ELT2. For example, the emission area EA of the pixel PXL may be finally partitioned by the second bank BNK2, and thus the color conversion layer CCL including color conversion particles QD of a desired amount and/or type may be supplied (or input) to the emission area EA. According to an embodiment, in forming the second bank BNK2, a mask used to form the pixel defining layer PDL may be used. For example, the second bank BNK2 and the pixel defining layer PDL may be formed using the same mask.

The light conversion pattern including the color conversion layer CCL and the color filter CF may be positioned in the emission area EA of the pixel PXL. The color conversion layer CCL may be provided in a form filling the opening OP (or a space formed by the opening OP and the second electrode ELT2) of the second bank BNK2.

The color conversion layer CCL may include the color conversion particles QD corresponding to a specific or given color. The color filter CF may selectively transmit light of the specific or given color.

The color conversion particles QD may be provided in the emission area EA to face the light emitting element LD, and may convert the light emitted from the light emitting element LD into the light of the specific or given color. For example, in case that the pixel PXL is a red pixel, the color conversion layer CCL may include color conversion particles QD of a red quantum dot that converts the light (or light of a first color) emitted from the light emitting element LD into light of a red color (or light of a second color). In case that the pixel PXL is a green pixel, the color conversion layer CCL may include color conversion particles QD of a green quantum dot that converts the light emitted from the light emitting element LD into light of a green color (or light of a third color). In case that the pixel PXL is a blue pixel, the color conversion layer CCL may include color conversion particles QD of a blue quantum dot that converts the light emitted from the light emitting element LD into light of a blue color (or light of a fourth color). According to an embodiment, the pixel PXL may include a light scattering layer including light scattering particles instead of the color conversion layer CCL including the color conversion particles QD. For example, in case that the light emitting element LD emits blue-based light, the pixel PXL may include the light scattering layer including the light scattering particles. The above-described light scattering layer may be omitted according to an embodiment. According to an embodiment, the pixel PXL may include a transparent polymer instead of the color conversion layer CCL.

The color filter CF may be disposed on the color conversion layer CCL of the pixel PXL and may include a color filter material that selectively transmits the light of the specific or given color converted by the color conversion layer CCL. In case that the pixel PXL is a red pixel, the color filter CF may include a red color filter. In case that the pixel PXL is a green pixel, the color filter CF may include a green color filter. In case that the pixel PXL is a blue pixel, the color filter CF may include a blue color filter.

According to an embodiment, the light conversion pattern layer LCPL may further include a cover layer provided between the second electrode ELT2 and the second bank BNK2 (and the color conversion layer CCL). The cover layer may completely cover or overlap the emission area EA and the non-emission area NEA to prevent water, moisture, or the like from flowing into the light emitting element LD from the outside. The cover layer may have a structure in which at least one inorganic insulating layer or at least one organic insulating layer may be alternately stacked each other.

According to an embodiment, the cover layer may be a transparent adhesive layer (or an adhesive layer) for strengthening adhesive force between the light conversion pattern layer LCPL and the display element layer DPL. For example, the cover layer may be an optically clear adhesive layer (optically clear adhesive), but the disclosure is not limited thereto. According to an embodiment, the cover layer may be a refractive index conversion layer for improving an emission luminance of the pixel PXL by converting a refractive index of the light emitted from the light emitting element LD and proceeding to the light conversion pattern layer LCPL. According to an embodiment, the cover layer may be formed of a heat and/or photo-curable resin and coated on the display element layer DPL in a liquid form, and cured by a curing process using heat and/or light.

In an embodiment, as shown in FIG. 4C, the light conversion pattern layer LCPL may further include a second reflective member RP provided in the opening OP of the second bank BNK2.

The second reflective member RP (or a second reflective pattern) may cover or overlap only a side surface (or an inclined surface) of the second bank BNK2 defining the opening OP. The second reflective member RP may not substantially overlap the second electrode ELT2 exposed by the opening OP (or a bottom surface of the recessed portion defined by the opening OP and the second electrode ELT2) in a plan view. For example, the second reflective member RP may be formed through anisotropic etching. In the anisotropic etching, an etching speed in a vertical direction (or the third direction DR3) may be greater than an etching speed in a horizontal direction. For example, a reflective layer for forming the second reflective member RP may be formed entirely on the substrate SUB, and the reflective layer in contact with an upper surfaces of the second bank BNK2 and the second electrode ELT2 may be etched through the anisotropic etching. Through this, the second reflective member RP disposed on the side surface (or the inclined surface) of the second bank BNK2 may be formed.

The second reflective member RP may allow light emitted from the color conversion layer CCL or transmitting the color conversion layer CCL to further proceed in the image display direction. The light may be focused on a specific or given area (for example, the emission area EA), and light output efficiency of the light emitting element LD may be improved. To this end, the second reflective member RP may be formed of a material having a reflectance. The second reflective member RP may be formed of a conductive material (or substance) having a reflectance. The second reflective member RP may include a same material or a similar material as the first reflective member 15, or may include one or more materials selected from the materials of the first reflective member 15.

As described above, the first bank BNK1 may be disposed in a form surrounding the light emitting element LD and may cover or overlap most of the first electrode ELT1. The first bank BNK1 may include a light blocking material such as a black matrix or a metal oxide layer. Therefore, the reflection of the external light by the first electrode ELT1 may be minimized.

The first reflective member 15 surrounding the outer circumferential surface of the light emitting element LD and/or the second reflective member RP covering or overlapping the side surface (or the inclined surface) of the second bank BNK2 may be further provided, and the first reflective member 15 and the second reflective member RP may include a material having a specific or given reflectance. Therefore, the light emitted from the light emitting element LD may further proceed in the image display direction (for example, the third direction DR3) by the first reflective member 15 and/or the second reflective member RP, and the light output efficiency of the light emitting element LD may be improved.

FIGS. 5A and 5B are schematic cross-sectional views illustrating an embodiment of the pixel taken along line I-I′ of FIG. 3. In FIGS. 5A and 5B, for convenience of description, the pixel is briefly shown based on the display element layer DPL (for example, the first electrode ELT1, the bank BNK, and the light emitting element LD). The pixel of FIGS. 5A and 5B may further include the pixel circuit layer PCL described with reference to FIG. 4A. According to an embodiment, the pixel of FIGS. 5A and 5B may further include the pixel defining layer PDL described with reference to FIG. 4A.

Referring to FIGS. 3, 4A, 5A, and 5B, since the protective layer PSV (or the substrate SUB), the first electrode ELT1, and the light emitting element LD are described with reference to FIG. 4A, a description of the protective layer PSV (or the substrate SUB), the first electrode ELT1, and the light emitting element LD is omitted. Since the bank BNK, the second electrode ELT2, the color conversion layer CCL, and the color filter CF are substantially the same as or similar to the bank BNK described with reference to FIG. 3, the color conversion layer CCL and the color filter CF described with reference to FIG. 4A, a repetitive description is omitted.

The bank BNK (a light blocking layer, or a light blocking pattern) may be provided or formed entirely on the substrate SUB to cover or overlap the first electrode ELT1 and the light emitting element LD.

The bank BNK may include a light blocking material that blocks light. For example, the bank BNK may include at least one black matrix material (for example, at least one light blocking material) among various types of black matrix materials, a color filter material of a specific or given color, and/or the like within the spirit and the scope of the disclosure. For example, the bank BNK may include a metal oxide or a metal oxide layer.

The bank BNK may be provided in a form filling an empty space between the light emitting element LD and the adjacent light emitting element LD. The bank BNK may contact the side surface (or the outer circumferential surface) of the light emitting element LD. The bank BNK may prevent the side surface of the light emitting element LD from contacting another conductive material (for example, the second electrode ELT2). The bank BNK may cover or overlap the first electrode ELT1 to prevent an electrical short circuit between the first electrode ELT1 and the second electrode ELT2. The bank BNK may cover or overlap the first electrode ELT1 to minimize the reflection of the external light by the first electrode ELT1. In other words, the holes H exposing the first electrode ELT1 may be formed in the bank BNK (or the recessed portion CC of the bank BNK), and the light emitting element LD may be disposed in each of the holes H. The outer circumferential surface between the first end and the second end of the light emitting element LD may contact the bank BNK.

The bank BNK may include the recessed portion CC formed in the emission area EA. The recessed portion CC may be a portion concavely formed in the direction opposite to the third direction DR3 based on an upper surface of the bank BNK in the non-emission area NEA. In other words, based on the upper surface of the bank BNK in the emission area EA, the bank BNK may include a protrusion protruding in the third direction DR3 in the non-emission area NEA. A thickness TH1 (or an average thickness) of the bank BNK in the emission area EA may be less than a thickness TH2 of the bank BNK in the non-emission area NEA. The recessed portion CC may be filled with a color conversion layer CCL, which will be described later.

For example, a light blocking layer including a black matrix material for the bank BNK may be formed entirely on the substrate SUB, and the light blocking layer may be partially etched using a halftone mask corresponding to the emission area EA. Through this, the recessed portion CC of the bank BNK may be formed. As another example, a light blocking layer including a metal material for the bank BNK may be formed entirely on the substrate SUB, the light blocking layer may be partially etched only in the emission area EA, and the recessed portion CC of the bank BNK may be formed.

In FIG. 5A, a side surface (or an inclined surface) of the bank BNK in the recessed portion CC is perpendicular to an upper surface of the substrate SUB or parallel to the third direction DR3, but the bank BNK is not limited thereto. For example, as shown in FIG. 5B, an inclination angle of the side surface of the bank BNK in the recessed portion CC may be an acute angle. In the recessed portion CC, the bank BNK may have a cross-sectional shape of a semicircle or a semi-ellipse in addition to a quadrangle and a trapezoid. The cross-sectional shape of the bank BNK (or the recessed portion CC) may be variously modified within a range in which the color conversion layer CCL may be filled.

The first and second banks BNK1 and BNK2 of FIG. 4A may be formed through different processes based on the second electrode ELT2, but the bank BNK of FIG. 5A may be formed through one process (for example, a photo process, or one mask). For example, according to the embodiment of FIG. 5A, a manufacturing process of the display device may be simplified.

The second electrode ELT2 (or the common electrode) may be provided and/or formed on the bank BNK (and the light emitting element LD). The second electrode ELT2 may contact the first semiconductor layer 11 (or the second end) of the light emitting element LD. The second electrode ELT2 may be entirely provided on the substrate SUB. The second electrode ELT2 may be a common layer commonly provided to the pixel PXL and pixels PXL adjacent thereto (for example, the first to third pixels PXL1 to PXL3 shown in FIG. 3). In an embodiment, the second electrode ELT2 may be a cathode electrode. The second semiconductor layer 13 (or the first end) of the light emitting element LD may contact the first electrode ELT1.

The light conversion pattern may be disposed on the second electrode ELT2, and the light conversion pattern may include the color conversion layer CCL and the color filter CF.

The color conversion layer CCL may be provided in a form filling the recessed portion CC of the bank BNK.

The color filter CF may be disposed on the color conversion layer CCL. As shown in FIG. 5A, the color filter CF may be provided not only in the emission area EA but also in the non-emission area NEA, but is not limited thereto. For example, as shown in FIG. 5B, the color filter CF may be provided only in the emission area EA. For example, the color filter CF may be provided in a form filling the recessed portion CC of the bank BNK.

As described above, the bank BNK including the recessed portion CC may be formed through one process (one photo process, or one mask), the second electrode ELT2 may be formed on the bank BNK, and the color conversion layer CCL (and the color filter CF) may be provided in the recessed portion CC of the bank BNK. Therefore, the manufacturing process of the display device may be more simplified.

The bank BNK may be disposed to cover or overlap most of the first electrode ELT1 and may include a light blocking material such as a black matrix or a metal oxide layer. Therefore, the reflection of the external light by the first electrode ELT1 may be minimized.

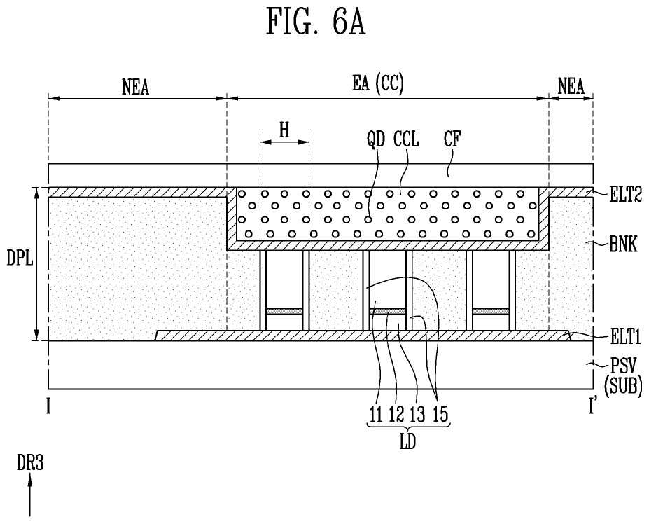

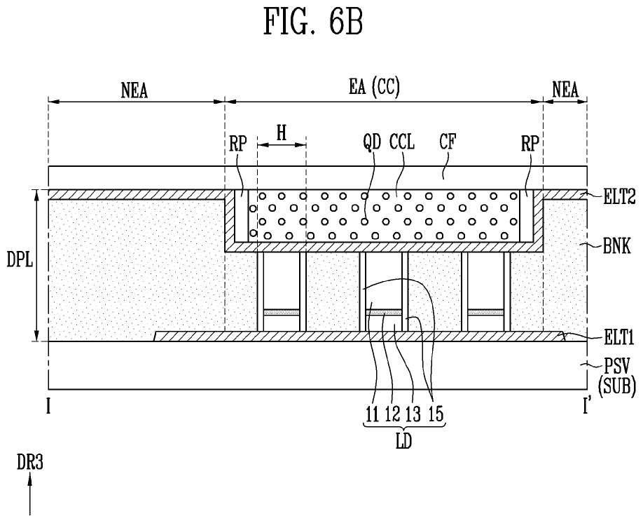

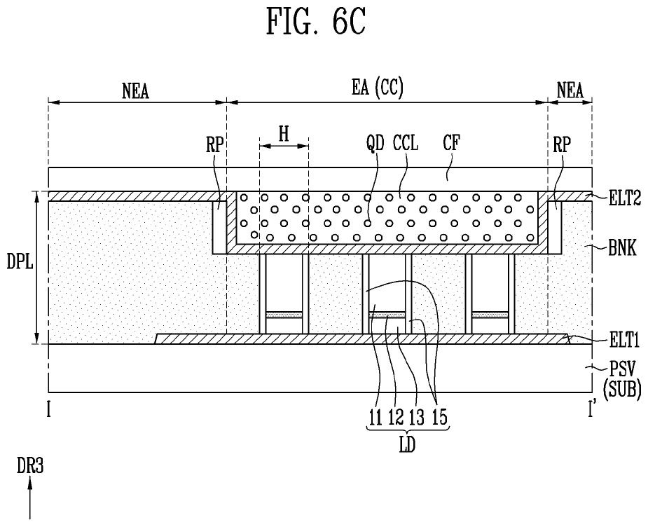

FIGS. 6A, 6B, and 6C are schematic cross-sectional views illustrating an embodiment of the pixel taken along line I-I′ of FIG. 3. FIGS. 6A, 6B, and 6C show schematic cross-sections of the pixel corresponding to FIG. 5A.

Referring to FIGS. 3, 5A, 6A, 6B, and 6C, the pixel of FIGS. 6A, 6B, and 6C may be substantially the same as or similar to the pixel of FIG. 5A except for the first reflective member 15 or the second reflective member RP. Therefore, a repetitive description is omitted.

As shown in FIG. 6A, the display element layer DPL may further include the first reflective member 15 (or the first reflective pattern) surrounding the outer circumferential surface between the first end and the second end of the light emitting element LD in the hole H of the bank BNK. The first reflective member 15 may be included in the light emitting element LD. For example, the first reflective member 15 may be formed in the manufacturing process of the light emitting element LD. The first reflective member 15 may be substantially the same as the first reflective member 15 described with reference to FIG. 4B.

As shown in FIGS. 6B and 6C, the display element layer DPL may further include the second reflective member RP (or the second reflective pattern) formed adjacent to the side surface of the bank BNK in the recessed portion CC. The second reflective member RP may be substantially the same as the second reflective member RP described with reference to FIG. 4C. The second reflective member RP may allow the light emitted from the color conversion layer CCL or transmitting the color conversion layer CCL to further proceed in the image display direction. Therefore, the light output efficiency of the light emitting element LD may be improved.

The second reflective member RP may be formed adjacent to only the side surface of the bank BNK forming the recessed portion CC, and may not substantially overlap a bottom surface of the recessed portion CC in a plan view.

In an embodiment, as shown in FIG. 6B, the second reflective member RP may be disposed between the second electrode ELT2 and the color conversion layer CCL (or the light conversion pattern). For example, after the second electrode ELT2 is formed, the second reflective member RP may be formed through anisotropic etching, and the color conversion layer CCL may be provided in the recessed portion CC.

In an embodiment, as shown in FIG. 6C, the second reflective member RP may be disposed between the second electrode ELT2 and the bank BNK. For example, after the recessed portion CC of the bank BNK is formed, the second reflective member RP may be formed through anisotropic etching, and the second electrode ELT2 may be formed.

As described above, the display element layer DPL (or the pixel) may further include the first reflective member 15 surrounding the outer circumferential surface of the light emitting element LD and/or the second reflective member RP covering or overlapping the side surface (or the inclined surface) of the recessed portion CC of the bank BNK, and the first reflective member 15 and the second reflective member RP may include a material having a specific or given reflectance. Therefore, the light output efficiency of the light emitting element LD may be improved.

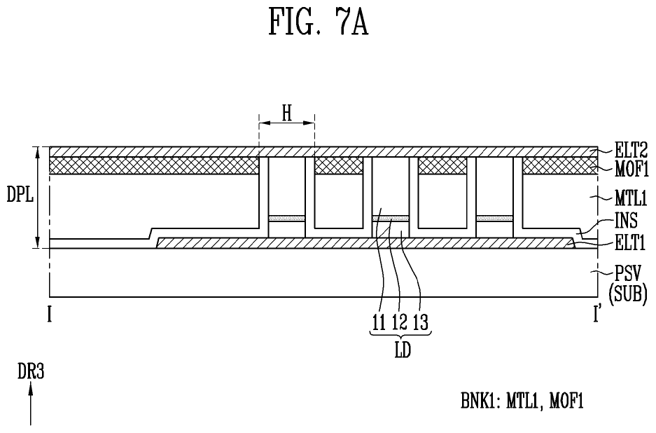

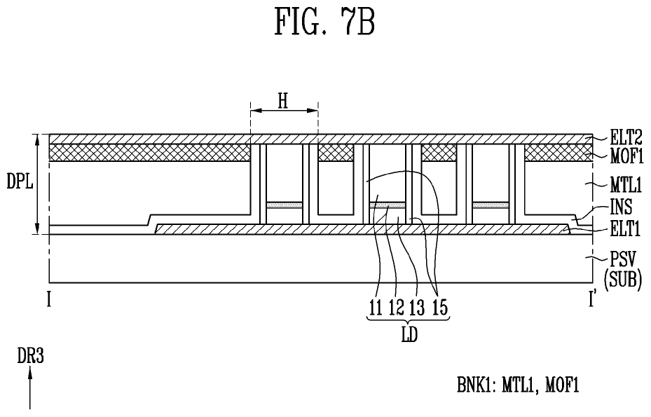

FIGS. 7A and 7B are schematic cross-sectional views illustrating an embodiment of the pixel taken along line I-I′ of FIG. 3. In FIGS. 7A and 7B, for convenience of description, the pixel is briefly shown based on the display element layer DPL (for example, the first electrode ELT1, the first bank BNK1, and the light emitting element LD). The pixel of FIGS. 7A and 7B may further include the pixel circuit layer PCL described with reference to FIG. 4A. According to an embodiment, the pixel of FIGS. 7A and 7B may further include the pixel defining layer PDL described with reference to FIG. 4A.

Referring to FIGS. 3, 4A, 7A, and 7B, the display element layer DPL (or a light emitting element layer) may be disposed on the protective layer PSV (or the substrate SUB). According to an embodiment, the display element layer DPL may be formed entirely in the display area DA of the display panel DP (refer to FIG. 1).

The display element layer DPL may include the first electrode ELT1, the light emitting element LD (or light emitting elements), an insulating layer INS, the first bank BNK1 (the planarization layer, the first light blocking layer, or the first light blocking pattern), and the second electrode ELT2. Since the first electrode ELT1, the light emitting element LD, and the second electrode ELT2 are described with reference to FIG. 4A, a description of the first electrode ELT1, the light emitting element LD, and the second electrode ELT2 is omitted.

The insulating layer INS may be provided or formed entirely on the substrate SUB to cover or overlap the first electrode ELT1 and the light emitting element LD. The insulating layer INS may cover or overlap the side surface (or the outer circumferential surface) of the light emitting element LD. The insulating layer INS may be disposed between the first bank BNK1 and the light emitting element LD, and between the first bank BNK1 and the first electrode ELT1. The insulating layer INS may prevent the side surface of the light emitting element LD from coming into contact with another conductive material (for example, the first bank BNK1 and the second electrode ELT2). The insulating layer INS may cover or overlap the first electrode ELT1 to prevent an electrical short circuit between the first electrode ELT1 and the second electrode ELT2. The second end (for example, the second end contacting the second electrode ELT2) of the light emitting element LD may be exposed by the insulating layer INS.

The insulating layer INS may be an inorganic insulating layer including an inorganic material. The inorganic insulating layer may include, for example, at least one of silicon nitride (SiNₓ), silicon oxide (SiOₓ), and silicon oxynitride (SiOₓN_{y}). According to an embodiment, the insulating layer INS may be formed of an organic insulating layer including an organic material. The insulating layer INS may be provided as a single layer, or may be provided as a multilayer of at least a double layer.

The first bank BNK1 may be provided or formed entirely on the substrate SUB to cover or overlap the first electrode ELT1.

In embodiments, the first bank BNK1 may include a metal oxide. In an embodiment, the first bank BNK1 may include a first metal oxide layer MOF1. For example, a first metal layer MTL1 that may function as a planarization layer may be formed through a sputtering technique or a metal ink. The first metal layer MTL1 may include a metal, such as copper (Cu), iron (Fe), or zinc (Zn), which may have a black color or function as a black matrix in case that oxidized. Thereafter, the first metal oxide layer MOF1 may be formed by oxidizing at least a portion of the first metal layer MTL1.

According to an embodiment, the first metal oxide layer MOF1 may be formed only on an upper surface of the first bank BNK1 (or the first metal layer MTL1). As shown in FIG. 7A, the first bank BNK1 may include the first metal layer MTL1 positioned between the first metal oxide layer MOF1 and the insulating layer INS. Even though the first metal oxide layer MOF1 is formed only on the upper surface of the first bank BNK1, most of light incident from the outside toward the first electrode ELT1 may be blocked. Therefore, the reflection of the external light by the first electrode ELT1 may be minimized. At least some of the light emitted from the light emitting element LD may be reflected by the first metal layer MTL1 to proceed in the third direction DR3. For example, the first metal layer MTL1 may function as a reflective member, and the light output efficiency of the light emitting element LD may be improved.

In an embodiment, the first metal oxide layer MOF1 may form the entire first bank BNK1. The first bank BNK1 may include only the first metal oxide layer MOF1, and only the first metal oxide layer MOF1 instead of the first metal layer MTL1 may be disposed between the insulating layer INS and the second electrode ELT2.

In an embodiment, as shown in FIG. 7B, the display element layer DPL may further include the first reflective member 15 surrounding the outer circumferential surface between the first end and the second end of the light emitting element LD in the hole H of the first bank BNK1. The first reflective member 15 may be included in the light emitting element LD. For example, the first reflective member 15 may be formed in the manufacturing process of the light emitting element LD. The first reflective member 15 may be substantially the same as the first reflective member 15 described with reference to FIG. 4B. The first reflective member 15 may also be applied to the pixel of FIG. 7A.

The second electrode ELT2 (or the common electrode) may be provided and/or formed on the first bank BNK1 (and the light emitting element LD). The second electrode ELT2 may contact the first semiconductor layer 11 (or the second end) of the light emitting element LD. The second electrode ELT2 may be entirely provided on the substrate SUB.

The pixel of FIGS. 7A and 7B may not include the color conversion layer CCL described with reference to FIG. 4A.

In case that the first, second, and third pixels PXL1, PXL2, and PXL3 described with reference to FIG. 3 emit light in different colors, the first, second, and third light emitting elements LD1, LD2, and LD3 may be light emitting diodes that emit light in different colors. For example, in case that the first pixel PXL1 is a red pixel emitting red light, the first light emitting element LD1 may be a first color light emitting diode emitting red light. For example, in case that the second pixel PXL2 is a green pixel emitting green light, the second light emitting element LD2 may be a second color light emitting diode emitting green light. For example, in case that the third pixel PXL3 is a blue pixel emitting blue light, the third light emitting element LD3 may be a third color light emitting diode emitting blue light. For example, even though the color conversion layer CCL is not provided, the display device may display an image of various colors.

As described above, the first bank BNK1 may include the first metal oxide layer MOF1 and may cover or overlap most of the first electrode ELT1. Therefore, the reflection of the external light by the first electrode ELT1 may be minimized.

The first metal oxide layer MOF1 may be formed only on the upper surface of the first bank BNK1 (or the first metal layer MTL1) or may form the entire first bank BNK1. In case that the first metal oxide layer MOF1 is formed only on the upper surface of the first bank BNK1, the first metal layer MTL1 under or below the first metal oxide layer MOF1 may function as a reflective member, and the light output efficiency of the light emitting element LD may be improved.

The insulating layer INS may be provided to cover or overlap the first electrode ELT1 and the outer circumferential surface of the light emitting element LD. Therefore, a short circuit between the first and second electrodes ELT1 and ELT2 and the light emitting element LD by the first bank BNK1 (or the first metal layer MTL1) may be prevented.

The pixel of FIGS. 7A and 7B may further include the light conversion pattern layer LCPL described with reference to FIGS. 4A and 4C.

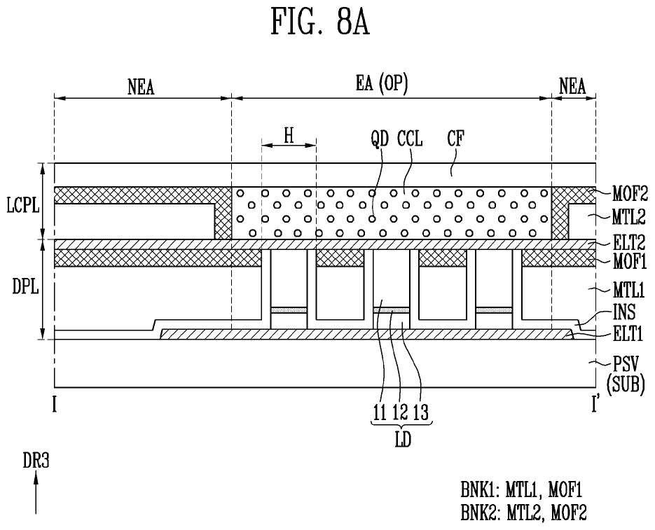

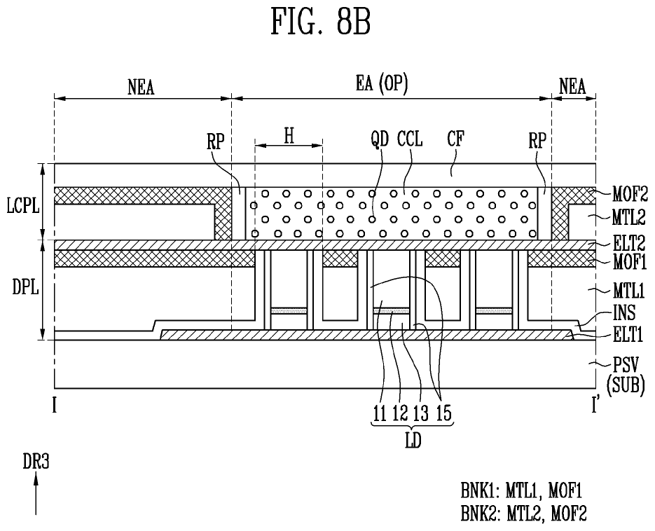

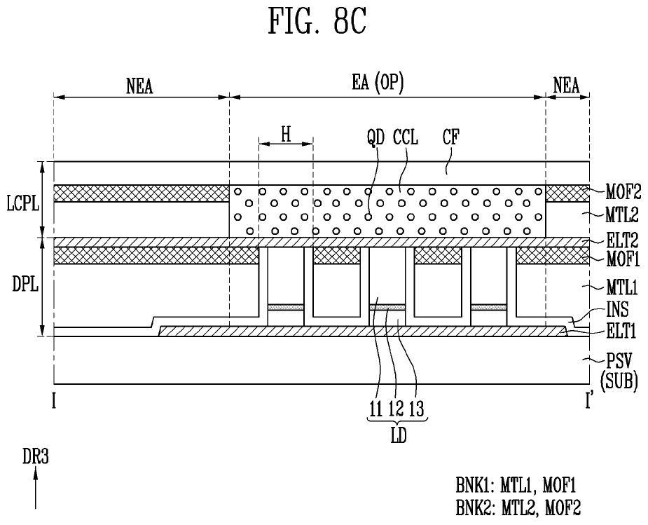

FIGS. 8A, 8B, and 8C are schematic cross-sectional views illustrating an embodiment of the pixel taken along line I-I′ of FIG. 3. In FIGS. 8A, 8B, and 8C, for convenience of description, the pixel is briefly shown based on the display element layer DPL (for example, the first electrode ELT1, the first bank BNK1, and the light emitting element LD). The pixel of FIGS. 8A, 8B, and 8C may further include the pixel circuit layer PCL and/or the pixel defining layer PDL described with reference to FIG. 4A.

Referring to FIGS. 3, 4A, 4C, 7A, 7B, 8A, 8B, and 8C, since the protective layer PSV (or the substrate SUB) and the display element layer DPL are described with reference to FIGS. 7A and 7B, a repetitive description is omitted.

The light conversion pattern layer LCPL may be further disposed on the display element layer DPL. The light conversion pattern layer LCPL may include the second bank BNK2 and the light conversion pattern, and the light conversion pattern may include the color conversion layer CCL (or the color conversion pattern) and the color filter CF. Since the color conversion layer CCL and the color filter CF are described with reference to FIGS. 4A and 4C, a description of the color conversion layer CCL and the color filter CF is omitted. Since the second bank BNK2 shown in FIGS. 8A, 8B, and 8C is similar to the second bank BNK2 of FIG. 4A, a repetitive description is omitted.

Similar to the first bank BNK1, the second bank BNK2 may include a metal oxide. In an embodiment, the second bank BNK2 may include a second metal oxide layer MOF2. For example, a second metal layer MTL2 may be formed, and an opening OP may be formed in the second metal layer MTL2 through etching. The second metal layer MTL2 may include a same material or a similar material as the first metal layer MTL1. For example, the second metal layer MTL2 may include a metal such as copper (Cu), iron (Fe), or zinc (Zn) that may have a black color or function as a black matrix in case that oxidized. Thereafter, the second metal oxide layer MOF2 may be formed by oxidizing at least a portion of the second metal layer MTL2.

According to an embodiment, the second metal oxide layer MOF2 may be formed only on a surface of the second bank BNK2 (or the second metal layer MTL2). As shown in FIG. 8A, the second bank BNK2 may include the second metal layer MTL2 positioned between the second metal oxide layer MOF2 and the second electrode ELT2. Even though the second metal oxide layer MOF2 is formed only on the surface of the second bank BNK2, most of the light incident on the non-emission area NEA from the outside may be blocked. The light incident on the emission area EA from the outside may be blocked by the first bank BNK1.

According to an embodiment, the second metal oxide layer MOF2 may form the entire second bank BNK2. The second bank BNK2 may be formed of a single layer including only the second metal oxide layer MOF2 among the second metal layer MTL2 and the second metal oxide layer MOF2 (refer to FIG. 4A).

In an embodiment, as shown in FIG. 8B, the light conversion pattern layer LCPL may further selectively include the second reflective member RP provided in the opening OP of the second bank BNK2. The second reflective member RP may be substantially the same as or similar to the second reflective member RP described with reference to FIG. 4C.

The second reflective member RP may allow the light emitted from the color conversion layer CCL or transmitting the color conversion layer CCL to further proceed in the image display direction. Therefore, the light output efficiency of the light emitting element LD may be improved.

In an embodiment, as shown in FIG. 8C, the second metal oxide layer MOF2 may be formed only on an upper surface of the second bank BNK2. For example, the second metal layer MTL2 may be formed, and thereafter, at least a portion of the second metal layer MTL2 may be oxidized to form the second metal oxide layer MOF2 only on the upper surface of the second metal layer MTL2 (or the second bank BNK2). Thereafter, the opening OP may be formed in the second metal layer MTL2 through etching. As another example, the second metal layer MTL2 may be formed, the opening OP may be formed in the second metal layer MTL2 through etching, and the color conversion layer CCL may be filled in the opening OP of the second metal layer MTL2. Thereafter, at least a portion of the second metal layer MTL2 may be oxidized to form the second metal oxide layer MOF2 only on the upper surface of the second metal layer MTL2 (or the second bank BNK2).

In case that the second metal oxide layer MOF2 is formed only on the upper surface of the second bank BNK2, a side surface (or an inclined surface) of the second metal layer MTL2 may be exposed in the opening OP, and the second metal layer MTL2 may be in contact with the color conversion layer CCL. The light emitted from the color conversion layer CCL or transmitting the color conversion layer CCL may be reflected by the second metal layer MTL2 to proceed in the third direction DR3. For example, the second metal layer MTL2 may function as a reflective member, and the light output efficiency of the light emitting element LD may be improved.

As described above, the second bank BNK2 may include the second metal oxide layer MOF2 and may block the light incident on the non-emission area NEA from the outside.

The second metal oxide layer MOF2 may form the entire second bank BNK2 or may be formed only on the surface or the upper surface of the second bank BNK2. In case that the second metal oxide layer MOF2 is formed only on the upper surface of the second bank BNK2, the second metal layer MTL2 under or below the second metal oxide layer MOF2 may function as a reflective member, and the light output efficiency of the light emitting element LD may be improved.

The first bank BNK1 described with reference to FIG. 4A may be applied to the pixel of FIGS. 8A, 8B, and 8C. For example, the first bank BNK1 may include the black matrix material, and the second bank BNK2 may include the second metal oxide layer MOF2.

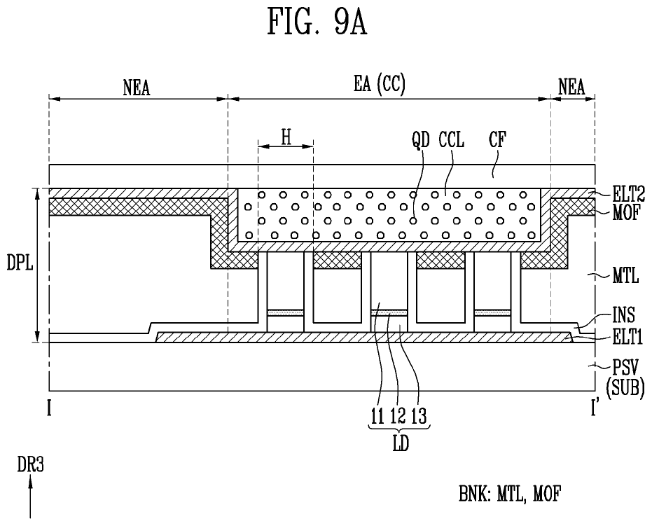

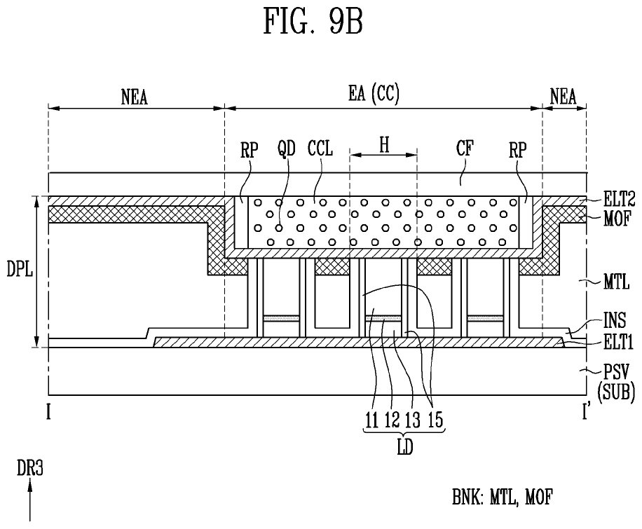

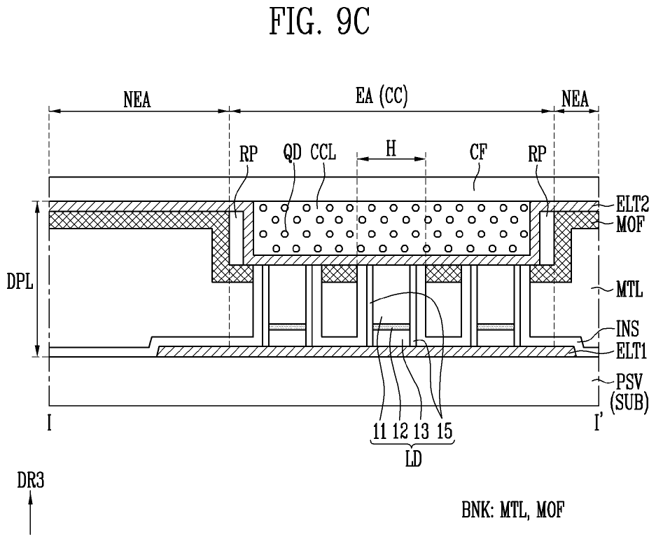

FIGS. 9A, 9B, and 9C are schematic cross-sectional views illustrating an embodiment of the pixel taken along line I-I′ of FIG. 3. FIGS. 9A, 9B, and 9C are schematic diagrams corresponding to FIGS. 5A, 6B, and 6C. FIGS. 9B and 9C show other embodiments in which the first reflective member 15 and/or the second reflective member RP are selectively provided.

Referring to FIGS. 3, 5A, 6B, 6C, 9A, 9B, and 9C, the pixel of FIGS. 9A, 9B, and 9C may be substantially the same as or similar to the pixels of FIGS. 5A, 6B, and 6C, respectively, except for the insulating layer INS and the bank BNK. Therefore, a repetitive description is omitted.

The insulating layer INS may be provided or formed entirely on the substrate SUB to cover or overlap the first electrode ELT1 and the light emitting element LD. The insulating layer INS may cover or overlap the side surface (or the outer circumferential surface) of the light emitting element LD. The second end (for example, the second end contacting the second electrode ELT2) of the light emitting element LD may be exposed by the insulating layer INS. The insulating layer INS may be substantially the same as or similar to the insulating layer INS described with reference to FIG. 7A.

The bank BNK (the light blocking layer, or the light blocking pattern) may be provided or formed entirely on the substrate SUB to cover or overlap the first electrode ELT1 and the light emitting element LD. The bank BNK may be substantially the same as or similar to the bank BNK described with reference to FIG. 5A except for a material. Therefore, a repetitive description is omitted.

The bank BNK may include a metal oxide. In an embodiment, the bank BNK may include a metal oxide layer MOF. For example, a metal layer MTL having a specific or given thickness (for example, the same thickness as the thickness of the bank BNK in the non-emission area NEA) may be formed entirely on the substrate SUB through sputtering technique or metal ink. The metal layer MTL may include a metal such as copper (Cu), iron (Fe), or zinc (Zn) which may have a black color or function as a black matrix in case that oxidized. Thereafter, a portion of the metal layer MTL corresponding to the emission area EA may be etched to form the recessed portion CC. Thereafter, the metal oxide layer MOF may be formed by oxidizing at least a portion of the metal layer MTL.

According to an embodiment, the metal oxide layer MOF may be formed only on a surface of the bank BNK (or the metal layer MTL). As shown in FIG. 9A, the bank BNK may include the metal layer MTL positioned between the metal oxide layer MOF and the insulating layer INS. Even though the metal oxide layer MOF is formed only on the surface of the bank BNK, most of the light incident from the outside toward the first electrode ELT1 may be blocked. Therefore, the reflection of the external light by the first electrode ELT1 may be minimized.

In an embodiment, the metal oxide layer MOF may form the entire bank BNK. The bank BNK may be formed of a single layer including only the metal oxide layer MOF among the metal layer MTL and the metal oxide layer MOF (refer to FIG. 5A).

As shown in FIGS. 9B and 9C, the display element layer DPL may include the second reflective member RP (or the second reflective pattern) formed adjacent to the side surface of the bank BNK in the recessed portion CC. The second reflective member RP may be substantially the same as the second reflective member RP described with reference to FIGS. 6B and 6C. The second reflective member RP may allow the light emitted from the color conversion layer CCL or transmitting the color conversion layer CCL to further proceed in the image display direction. Therefore, the light output efficiency of the light emitting element LD may be improved.

The second reflective member RP may be formed adjacent to only the side surface of the bank BNK forming the recessed portion CC, and may not substantially overlap the bottom surface of the recessed portion CC in a plan view.

In an embodiment, as shown in FIG. 9B, the second reflective member RP may be disposed between the second electrode ELT2 and the color conversion layer CCL (or the light conversion pattern).

In an embodiment, as shown in FIG. 9C, the second reflective member RP may be disposed between the second electrode ELT2 and the bank BNK (or the metal oxide layer MOF).

As described above, since the bank BNK including the recessed portion CC is integrally formed, a manufacturing process of the display device may be more simplified. The bank BNK may include the metal oxide layer MOF and may cover or overlap most of the first electrode ELT1. Therefore, the reflection of the external light by the first electrode ELT1 may be minimized. Furthermore, the display element layer DPL (or the pixel) may further include the first reflective member 15 surrounding the outer circumferential surface of the light emitting element LD and/or the second reflective member RP covering or overlapping the side surface (or the inclined surface) of the recessed portion CC of the bank BNK, and the first reflective member 15 and the second reflective member RP may include a material having a specific or given reflectance. Therefore, the light output efficiency of the light emitting element LD may be improved.

FIG. 10 is a schematic diagram illustrating a light emitting element according to an embodiment of the disclosure.

Referring to FIG. 10, the light emitting element LD may include a first semiconductor layer 11, a second semiconductor layer 13, and an active layer 12 interposed between the first semiconductor layer 11 and the second semiconductor layer 13. For example, the light emitting element LD may implemented as a light emitting stack in which the second semiconductor layer 13, the active layer 12, and the first semiconductor layer 11 may be sequentially stacked each other.

The light emitting element LD may be provided in a shape extending in one direction or a direction. In case that an extension direction of the light emitting element LD is referred to as a length L direction, the light emitting element LD may include the first end (or a lower end) and the second end (or an upper end) along the extension direction. In an embodiment, the length L direction may be parallel to the third direction DR3. Any one of the first semiconductor layer 11 and the second semiconductor layer 13 may be positioned at the first end EP1 (or the lower end) of the light emitting element LD, and the other of the first semiconductor layer 11 and the second semiconductor layer 13 may be positioned at the second end EP2 (or the upper end) of the light emitting element LD. For example, the second semiconductor layer 13 may be positioned at the first end EP1 (or the lower end) of the light emitting element LD, and the first semiconductor layer 11 may be positioned at the second end EP2 (or the upper end) of the light emitting element LD.

The light emitting element LD may be provided in various shapes. For example, the light emitting element LD may have a rod-like shape or a bar-like shape which is long in the length L direction (for example, having an aspect ratio greater than 1). The light emitting element LD may have a rod-like or a bar-like shape which is short in the length L direction (for example, having an aspect ratio less than 1).

In an embodiment, the light emitting element LD may have a column shape in which a diameter D1 of the first end EP1 and a diameter D2 of the second end EP2 are different from each other. For example, the light emitting element LD may have a column shape in which the diameter D1 of the first end EP1 is less than the diameter D2 of the second end EP2. The light emitting element LD may have an elliptical column shape in which a diameter increases upward along the length L direction (or the third direction DR3).

A length L of the light emitting element LD in the length L direction may be greater or less than the diameter D1 (a width of a first cross section) of the first end EP1 and the diameter D2 (a width of a second cross section) of the second end EP2. For example, the length L of the light emitting element LD may be greater than the diameter D1 of the first end EP1 and less than the diameter D2 of the second end EP2. However, the disclosure is not limited thereto, and according to an embodiment, the length L of the light emitting element LD may be the same as the diameter D1 of the first end EP1 or may be the same as the diameter D2 of the second end EP2. The above-described light emitting element LD may include, for example, a light emitting diode (LED) manufactured so as to have the diameter and/or the length L of about nano scale or micro scale.

A size of the light emitting element LD may be variously changed to correspond to requirements (or a design condition) of a lighting device or a self-luminous display device to which the light emitting element LD is applied.

The second semiconductor layer 13 may include, for example, at least one p-type semiconductor layer. For example, the second semiconductor layer 13 may include at least one semiconductor material among InAlGaN, GaN, AlGaN, InGaN, AlN, and InN, and may include a p-type semiconductor layer doped with a second conductive dopant (or a p-type dopant) such as Mg, Zn, Ca, Sr, or Ba. However, the material forming the second semiconductor layer 13 is not limited thereto, and various other materials may form the second semiconductor layer 13. In an embodiment, the second semiconductor layer 13 may include a gallium nitride (GaN) semiconductor material doped with the second conductive dopant (or the p-type dopant). The second semiconductor layer 13 may include an upper surface in contact with the active layer 12 and a lower surface exposed to the outside along the length L direction of the light emitting element LD.

The active layer 12 may be disposed on the second semiconductor layer 13 and may be formed in a single quantum well structure or a multiple quantum well structure. For example, in case that the active layer 12 is formed in the multiple quantum well structure, in the active layer 12, a barrier layer (not shown), a strain reinforcing layer, and a well layer may be periodically and repeatedly stacked as one unit. The strain reinforcing layer may have a lattice constant less than that of the barrier layer to further reinforce strain, for example, a compression strain, applied to the well layer. However, a structure of the active layer 12 is not limited to the above-described embodiment.

The active layer 12 may emit light of a wavelength of 400 nm to 900 nm, and may use a double hetero structure. In an embodiment of the disclosure, a clad layer (not shown) doped with a conductive dopant may be formed on and/or under or below the active layer 12 along the length L direction of the light emitting element LD. For example, the clad layer may be formed of an AlGaN layer or an InAlGaN layer. According to an embodiment, a material such as AlGaN or InAlGaN may be used to form the active layer 12. Various other materials may form the active layer 12. The active layer 12 may include a first surface contacting the second semiconductor layer 13 and a second surface contacting the first semiconductor layer 11.

In case that a corresponding signal is applied to each of the first end EP1 and the second end EP2 of the light emitting element LD, the light emitting element LD emits light while an electron-hole pair is combined in the active layer 12. By controlling light emission of the light emitting element LD by using such a principle, the light emitting element LD may be used as a light source (or a light emitting source) of various light emitting devices including the pixel PXL of the display device.

The first semiconductor layer 11 may be disposed on the active layer 12 and may include a semiconductor layer of a type different from that of the second semiconductor layer 13. For example, the first semiconductor layer 11 may include at least one n-type semiconductor layer. For example, the first semiconductor layer 11 may include any one semiconductor material among InAlGaN, GaN, AlGaN, InGaN, AlN, and InN, and may be an n-type semiconductor layer doped with a first conductive dopant (or an n-type dopant) such as Si, Ge, or Sn. However, the material forming the first semiconductor layer 11 is not limited thereto, and various other materials may form the first semiconductor layer 11. In an embodiment, the first semiconductor layer 11 may include a gallium nitride (GaN) semiconductor material doped with the first conductive dopant (or the n-type dopant). The first semiconductor layer 11 may include a lower surface in contact with the active layer 12 and an upper surface exposed to the outside along the length L direction of the light emitting element LD. The upper surface of the first semiconductor layer 11 may be the second end EP2 (or the upper end) of the light emitting element LD.

In an embodiment, the second semiconductor layer 13 and the first semiconductor layer 11 may have different thicknesses in the length L direction (or the third direction DR3) of the light emitting element LD. For example, the first semiconductor layer 11 may have a thickness relatively greater than that of the second semiconductor layer 13 in the length L direction (or the third direction DR3) of the light emitting element LD. Therefore, the active layer 12 of the light emitting element LD may be positioned closer to the lower surface of the second semiconductor layer 13 than the upper surface of the first semiconductor layer 11.

Although the first semiconductor layer 11 and the second semiconductor layer 13 are shown as being formed of one layer or a layer, the disclosure is not limited thereto. In an embodiment, according to the material of the active layer 12, each of the first semiconductor layer 11 and the second semiconductor layer 13 may further include one or more layers, for example, a clad layer and/or a tensile strain barrier reducing (TSBR) layer. The TSBR layer may be a strain relief layer disposed between semiconductor layers having different lattice structures and serving as a buffer to reduce a difference of a lattice constant. The TSBR layer may be formed of a p-type semiconductor layer such as p-GaInP, p-AlInP, and p-AlGaInP, but the disclosure is not limited thereto.

According to an embodiment, the light emitting element LD may further include an additional electrode (not shown, hereinafter referred to as a “first additional electrode”) disposed under or below the second semiconductor layer 13 in addition to the above-described first semiconductor layer 11, active layer 12, and second semiconductor layer 13. According to an embodiment, the light emitting element LD may further include another additional electrode (not shown, hereinafter referred to as a “second additional electrode”) disposed on the first semiconductor layer 11.

Each of the first and second additional electrodes may be an ohmic contact electrode, but the disclosure is not limited thereto. According to an embodiment, the first and second additional electrodes may be schottky contact electrodes. The first and second additional electrodes may include a conductive material. For example, the first and second additional electrodes may include an opaque metal using chromium (Cr), titanium (Ti), aluminum (Al), gold (Au), nickel (Ni), oxide thereof, alloy thereof, and the like alone or in combination, but the disclosure is not limited thereto. According to an embodiment, the first and second additional electrodes may also include transparent conductive oxide such as indium tin oxide (ITO), indium zinc oxide (IZO), zinc oxide (ZnO), indium gallium zinc oxide (IGZO), and indium tin zinc oxide (ITZO).

The materials included in the first and second additional electrodes may be the same as or different from each other. The first and second additional electrodes may be substantially transparent or translucent. Therefore, the light generated by the light emitting element LD may transmit each of the first and second additional electrodes and may be emitted to the outside of the light emitting element LD. According to an embodiment, in case that the light generated by the light emitting element LD does not transmit the first and second additional electrodes and is emitted to the outside of the light emitting element LD through a region except for the both ends EP1 and EP2 of the light emitting element LD, the first and second additional electrodes may include an opaque metal.

In an embodiment, the light emitting element LD may further include an insulating film 14. However, according to an embodiment, the insulating film 14 may be omitted or may be provided so as to cover or overlap only a portion of a light emitting stack 10.

The insulating film 14 may prevent an electrical short circuit that may occur in case that the active layer 12 contacts a conductive material other than the first and second semiconductor layers 11 and 13. The insulating film 14 may minimize a surface defect of the light emitting element LD to improve a lifespan and light emission efficiency of the light emitting element LD. In case that light emitting elements LD are closely disposed, the insulating film 14 may prevent an unwanted short circuit that may occur between the light emitting elements LD. In case that the active layer 12 may prevent an occurrence of a short circuit with an external conductive material, presence or absence of the insulating film 14 is not limited.

The insulating film 14 may be provided in a form entirely surrounding (or covering) an outer circumferential surface of the light emitting stack 10 including the second semiconductor layer 13, the active layer 12, and the first semiconductor layer 11.

In the above-described embodiment, the insulating film 14 entirely surround the outer circumferential surface of each of the second semiconductor layer 13, the active layer 12, and the first semiconductor layer 11, but the disclosure is not limited thereto. According to an embodiment, in case that the light emitting element LD may include the first additional electrode, the insulating film 14 may entirely surround an outer circumferential surface of each of the first additional electrode, the second semiconductor layer 13, the active layer 12, and the first semiconductor layer 11. According to an embodiment, the insulating film 14 may not entirely surround the outer circumferential surface of the first additional electrode, or may surround only a portion of the outer circumferential surface of the first additional electrode and may not surround the remaining of the outer circumferential surface of the first additional electrode. According to an embodiment, in case that the first additional electrode is disposed at the first end EP1 (or the lower end) of the light emitting element LD and the second additional electrode is disposed at the second end EP2 (or the upper end) of the light emitting element LD, the insulating film 14 may expose at least one region of each of the first and second additional electrodes.

The insulating film 14 may include a transparent insulating material. For example, the insulating film 14 may include at least one insulating material selected from a group consisting of silicon oxide (SiOₓ), silicon nitride (SiNₓ), silicon oxynitride (SiOₓN_{y}), aluminum oxide (AlOₓ), titanium oxide (TiOₓ), hafnium oxide (HfOₓ), titanium strontium oxide (SrTiOₓ), cobalt oxide (CoₓO_{y}), Magnesium oxide (MgO), zinc oxide (ZnO), rucenium oxide (RuOₓ), nickel oxide (NiO), tungsten oxide (WOₓ), tantalum oxide (TaOₓ), gadolinium oxide (GdOₓ), zirconium oxide (ZrOₓ), gallium Oxide (GaOₓ), vanadium oxide (VₓO_{y}), ZnO:Al, ZnO:B, InₓO_{y}:H, niobium oxide (NbₓO_{y}), magnesium fluoride (MgFₓ), aluminum fluoride (A1Fₓ), Alucone polymer film, titanium nitride (TiN), tantalum nitride (TaN), aluminum nitride (AlNₓ), gallium nitride (GaN), tungsten nitride (WN), hafnium nitride (HfN), niobium nitride (NbN), gadolinium nitride (GdN), zirconium nitride (ZrN), and vanadium nitride (VN), but the disclosure is not limited thereto, and various materials having insulating properties may be used as the material of the insulating film 14.

The insulating film 14 may be provided in a form of a single layer, or may be provided in a form of multiple layers including at least a double layer. For example, in case that the insulating film 14 is formed of a double layer including a first layer and a second layer which may be sequentially stacked each other, the first layer and the second layer may be formed of different materials (or substances), and may be formed in different processes. According to an embodiment, the first layer and the second layer may include a same material or a similar material.

The light emitting element LD may further include a first reflective member 15 surrounding an outer circumferential surface of the insulating film 14.

The first reflective member 15 may be formed of a material having a reflectance in order to focus the light emitted from the light emitting element LD to a specific or given area while allowing the light to proceed in the image display direction. For example, the first reflective member 15 may be formed of a conductive material (or substance) having a reflectance. The first reflective member 15 may include an opaque metal. The first reflective member 15 may include a same material or a similar material as the reflective pattern or the first electrode ELT1, or may include one or more materials selected from materials of the first electrode ELT1.

In an embodiment, the first reflective member 15 may have a constant inclination in an oblique direction inclined to the third direction DR3 in order to collimate the light emitted from the active layer 12 of the light emitting element LD to a specific or given area. As described above, since the light emitting element LD has the elliptical column shape of which the diameter increases upward along the length L direction (or the third direction DR3), the insulating film 14 surrounding the outer circumferential surface of the light emitting stack 10 and the first reflective member 15 surrounding the outer circumferential surface of the insulating film 14 may have a constant inclination in a schematic cross-sectional view. In case that the first reflective member 15 has a constant inclination, the light emitted from the active layer 12 of the light emitting element LD may be reflected by the first reflective member 15 to be focused only to a specific or given area. For example, the first reflective member 15 may focus the light emitted radially (in a radial shape) from the active layer 12 of the light emitting element LD to a specific or given area.

The above-described first reflective member 15 may partially surround the outer circumferential surface of the insulating film 14 to expose a portion of the insulating film 14. At this time, a height h of the first reflective member 15 in the third direction DR3 may be less than the length L of the light emitting element LD. One end (or a lower end) of the first reflective member 15 may be positioned on the same line (or on the same plane) as the first end EP1 of the light emitting element LD, and another end (or an upper end) may be positioned below the second end EP2 of the light emitting element LD in the third direction DR3.

In the light emitting element LD, the second semiconductor layer 13 and the first semiconductor layer 11 including different types of semiconductor layers may be positioned to face each other in the length L direction (or the third direction DR3) of the corresponding light emitting element LD. The second semiconductor layer 13 may be positioned at the first end EP1 (or the lower end) of the light emitting element LD, and the first semiconductor layer 11 may be positioned at the second end EP2 (or the upper end). The light emitting element LD may be a light emitting element having a vertical structure in which the second semiconductor layer 13, the active layer 12, and the first semiconductor layer 11 may be sequentially stacked each other in the length L direction (or the third direction DR3).

The above-described light emitting element LD may be used as a light emitting source (or a light source) of various display devices.

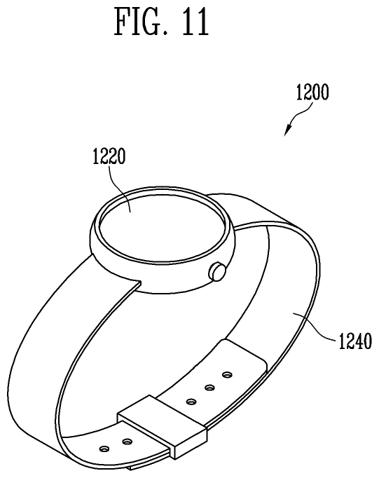

FIGS. 11 to 14 are schematic diagrams illustrating examples of a display device according to embodiments of the disclosure.

First, referring to FIGS. 1 and 11, the display device may be applied to a smart watch 1200 including a display unit 1220 and a strap unit 1240.

The smart watch 1200 may be a wearable electronic device and may have a structure in which the strap unit 1240 is mounted on a wrist of a user. Here, the display device may be applied to the display unit 1220, and thus image data including time information may be provided to the user.

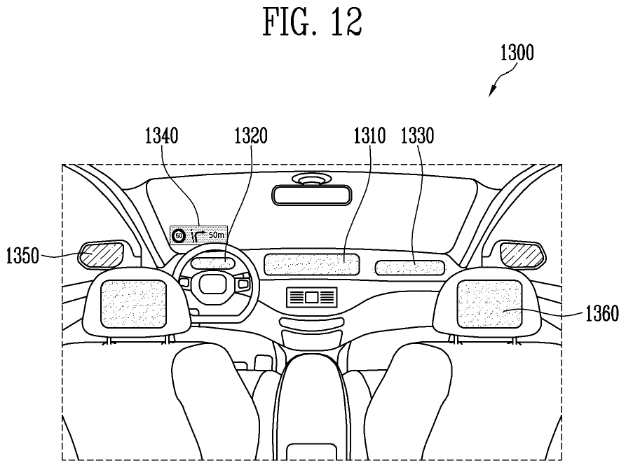

Referring to FIGS. 1 and 12, the display device may be applied to an automotive display 1300. Here, the automotive display 1300 may mean an electronic device provided inside and outside a vehicle to provide the image data.

For example, the display device may be applied to at least one of an infotainment panel 1310, a cluster 1320, a co-driver display 1330, a head-up display 1340, a side mirror display 1350, and a rear seat display 1360, which are provided in the vehicle.

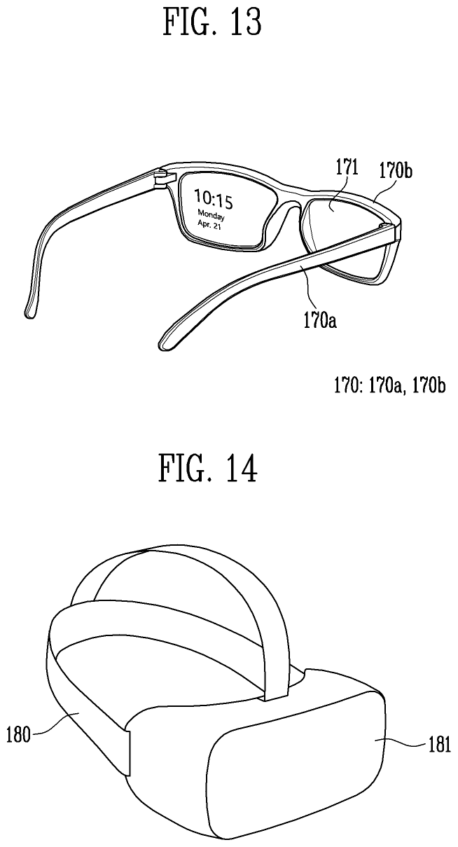

Referring to FIGS. 1 and 13, the display device may be applied to a smart glass including a frame 170 and a lens unit 171. The smart glass may be a wearable electronic device that may be worn on a face of a user, and may have a structure in which a portion of the frame 170 is folded or unfolded. For example, the smart glass may be a wearable device for augmented reality (AR).

The frame 170 may include a housing 170b supporting the lens unit 171 and a leg unit 170a for wearing of the user. The leg unit 170a may be connected to the housing 170b by a hinge and may be folded or unfolded.

The frame 170 may include a battery, a touch pad, a microphone, a camera, and the like therein. The frame 170 may include a projector that outputs light, a processor that controls a light signal or the like, and the like therein.

The lens unit 171 may be an optical member that transmits light or reflects light. The lens unit 171 may include glass, transparent synthetic resin, or the like within the spirit and the scope of the disclosure.

The lens unit 171 may reflect an image by a light signal transmitted from the projector of the frame 170 by a rear surface (for example, a surface of a direction facing an eye of the user) of the lens unit 171 to allow the eye of the user to recognize the image. For example, as shown in the drawing, the user may recognize information such as time and date displayed on the lens unit 171. For example, the lens unit 171 may be one type of the display device, and the display device may be applied to the lens unit 171.

Referring to FIGS. 1 and 14, the display device may be applied to a head mounted display (HMD) including a head mounting band 180 and a display storage case 181. The HMD is a wearable electronic device that may be worn on a head of a user.

The head mounting band 180 is a portion connected to the display storage case 181 and fixing the display storage case 181. In the drawing, the head mounting band 180 is shown to be able to surround an upper surface and both side surfaces of the head of the user, but the disclosure is not limited thereto. The head mounting band 180 may be for fixing the HMD to the head of the user, and may be formed in an eyeglass frame form or a helmet form.

The display storage case 181 may accommodate the display device and may include at least one lens. The at least one lens is a portion that provides an image to the user. For example, the display device may be applied to a left-eye lens and a right-eye lens implemented in the display storage case 181.

Although the disclosure has been described with reference to the embodiments, those skilled in the art will understand that the disclosure may be variously modified and changed without departing from the spirit and technical area of the disclosure described in the claims.

Therefore, the technical scope of the disclosure should not be limited to the contents described in the detailed description of the specification, but should also be defined by the claims.

What is claimed is:

1. A display device comprising:
a first electrode disposed on a substrate;
a light blocking layer disposed on the substrate, the light blocking layer including:
a recessed portion recessed toward the first electrode; and
holes in the recessed portion exposing the first electrode;
light emitting elements disposed in the holes, each of the light emitting elements including a first end electrically contacting the first electrode;
a second electrode disposed on the light blocking layer, the second electrode electrically contacting a second end of each of the light emitting elements; and
a light conversion pattern disposed in the recessed portion of the light blocking layer.

2. The display device according to claim 1, wherein an outer circumferential surface between the first end and the second end of each of the light emitting elements contacts the light blocking layer.

3. The display device according to claim 1, wherein the light blocking layer includes a black matrix material.

4. The display device according to claim 1, wherein the light conversion pattern includes a color conversion layer that converts light of a first color emitted from the light emitting elements into light of a second color.

5. The display device according to claim 4, wherein the light conversion pattern includes a color filter disposed on the color conversion layer, the color filter transmitting the light of the second color.

6. The display device according to claim 1, further comprising:
a first reflective member surrounding an outer circumferential surface between the first end and the second end of each of the light emitting elements.

7. The display device according to claim 1, further comprising:
a second reflective member overlapping a side surface of the recessed portion of the light blocking layer in a plan view and not substantially overlapping a bottom surface of the recessed portion of the light blocking layer in a plan view.

8. The display device according to claim 7, wherein the second reflective member is disposed between the second electrode and the light conversion pattern.

9. The display device according to claim 7, wherein the second reflective member is disposed between the light blocking layer and the second electrode.

10. The display device according to claim 1, wherein the light blocking layer includes a metal oxide.

11. The display device according to claim 10, wherein the light blocking layer comprises:
a metal layer disposed on the substrate; and
a metal oxide layer disposed on a surface of the metal layer.

12. The display device according to claim 10, further comprising:
an insulating layer disposed between the first electrode and the light blocking layer and disposed between the light blocking layer and the light emitting elements.

13. The display device according to claim 1, wherein
the first electrode includes a conductive material that reflects light, and
the second electrode includes a transparent conductive material that transmits light.

14. The display device according to claim 1, wherein each of the light emitting elements comprises:
a second semiconductor layer electrically connected to the first electrode;
a first semiconductor layer electrically connected to the second electrode; and
an active layer disposed between the second semiconductor layer and the first semiconductor layer.

15. The display device according to claim 1, further comprising:
a pixel defining layer disposed between an edge of the first electrode and the light blocking layer, the pixel defining layer defining an emission area.

16. A display device comprising:
a first electrode disposed on a substrate;
light emitting elements disposed on the first electrode, each of the light emitting elements including a first end electrically contacting the first electrode;
a second electrode disposed on the light emitting elements, the second electrode electrically contacting a second end of each of the light emitting elements; and
a light blocking layer disposed between the first electrode and the second electrode and disposed between the light emitting elements,
wherein the light blocking layer includes a metal oxide.

17. The display device according to claim 16, wherein the light blocking layer comprises:
a metal layer disposed on the substrate; and
a metal oxide layer disposed on a surface of the metal layer.

18. The display device according to claim 16, further comprising:
an insulating layer disposed between the first electrode and the light blocking layer and disposed between the light blocking layer and the light emitting elements.

19. The display device according to claim 16, further comprising:
a first reflective member surrounding an outer circumferential surface between the first end and the second end of each of the light emitting elements.

20. The display device according to claim 16, further comprising:
a bank disposed on the second electrode, the bank including an opening corresponding to the light emitting elements; and
a light conversion pattern disposed in the opening of the bank,
wherein the bank includes a metal oxide.

21. The display device according to claim 20, further comprising:
a second reflective member overlapping a side surface of the opening of the bank in a plan view.

22. A display device comprising:
a first electrode disposed on a substrate;
light emitting elements disposed on the first electrode, each of the light emitting elements including a first end electrically contacting the first electrode;
a second electrode disposed on the light emitting elements, the second electrode electrically contacting a second end of each of the light emitting elements;
a light blocking layer disposed between the first electrode and the second electrode and disposed between the light emitting elements;
a bank disposed on the second electrode, the bank including an opening corresponding to the light emitting elements;
a light conversion pattern disposed in the opening of the bank; and
a reflective member overlapping a side surface of the opening of the bank in a plan view.
